(19) United States
(12) Patent Application Publication
(10) Pub. No.: US 2023/0238405 A1
(43) Pub. Date: Jul. 27, 2023

(54) SEMICONDUCTOR DEVICE AND ELECTRONIC DEVICE

(71) Applicant: SONY SEMICONDUCTOR SOLUTIONS CORPORATION, Kanagawa (JP)

(72) Inventors: Shohei SHIMADA, Kanagawa (JP); Yusuke OTAKE, Kanagawa (JP); Toshifumi WAKANO, Kanagawa (JP)

(73) Assignee: SONY SEMICONDUCTOR SOLUTIONS CORPORATION, Kanagawa (JP)

(21) Appl. No.: 18/001,704

(22) PCT Filed: May 7, 2021
(86) PCT No.: PCT/JP2021/017542

§ 371 Date: Dec. 13, 2022

(30) Foreign Application Priority Data
Jun. 24, 2020 (JP) 2020-108372

(51) Int. Cl. H01L 27/146; H01L 31/107

(52) U.S. Cl. CPC H01L 27/1461; H01L 31/1075; H01L 27/1463; H01L 27/14643

(57) ABSTRACT

Provided is a semiconductor device capable of achieving high detection efficiency and low jitter without depending on an increase in thickness of a substrate. A semiconductor device is provided with a plurality of pixels in each of which an avalanche photodiode element that photoelectrically converts incident light is formed, and each of the plurality of pixels is provided with a substrate including a first semiconductor material, and a stacked portion stacked on a surface on a light incident side of the substrate and including a second semiconductor material different from the first semiconductor material.

### TECHNICAL FIELD

The present disclosure (present technology) relates to a semiconductor device and an electronic device provided with the semiconductor device.

### BACKGROUND ART

An avalanche photodiode (APD) includes a Geiger mode in which it is operated at a bias voltage higher than a breakdown voltage and a linear mode in which it is operated at a slightly higher bias voltage near the breakdown voltage. The Geiger mode avalanche photodiode is also referred to as a single photon avalanche photodiode (SPAD).

The SPAD is a device capable of detecting one photon for each pixel by multiplying a carrier generated by photoelectric conversion in a PN junction region of a high electric field provided for each pixel.

By the way, there has been a demand for improvement in sensitivity of SPAD pixels, and thus, proposed is a method for improving detection efficiency referred to as photon detection efficiency (PDE) while securing a wide area of a multiplication region (for example, Patent Document 1).

### CITATION LIST

### Patent Document

Patent Document 1: Japanese Patent Application Laid-Open No. 2018-201005

### SUMMARY OF THE INVENTION

### Problems to be Solved by the Invention

By the way, in the SPAD, since silicon (Si) is used in a substrate, sensitivity in an infrared (IR) region is low, and it is necessary to make Si thick in order to improve PDE. When Si is made thick, time for a photoelectrically converted electron to reach a multiplication region becomes long, and there is a concern about deterioration in jitter characteristic in a case where this is used as laser imaging detection and ranging (LIDAR).

The present disclosure has been achieved in view of such circumstances, and an object thereof is to provide a semiconductor device and an electronic device capable of achieving high detection efficiency and low jitter without depending on an increase in thickness of a substrate.

### Solutions to Problems

An aspect of the present disclosure is a semiconductor device including a plurality of pixels in each of which an avalanche photodiode element that photoelectrically converts incident light is formed, each of the plurality of pixels provided with a substrate including a first semiconductor material, and a stacked portion stacked on a surface on a light incident side of the substrate and including a second semiconductor material different from the first semiconductor material.

Another aspect of the present disclosure is an electronic device including a semiconductor device including a plurality of pixels in each of which an avalanche photodiode element that photoelectrically converts incident light is formed, each of the plurality of pixels provided with a substrate including a first semiconductor material, and a stacked portion stacked on a surface on a light incident side of the substrate and including a second semiconductor material different from the first semiconductor material.

### BRIEF DESCRIPTION OF DRAWINGS

FIG. 1A is a schematic configuration diagram illustrating a pixel circuit using an SPAD as a solid-state imaging device according to a first embodiment of the present technology.

FIG. 1B is a diagram for explaining an operation in a case where a pixel is an active pixel in the first embodiment of the present technology.

FIG. 2 is a cross-sectional view illustrating an example of three pixels according to the first embodiment of the present technology.

FIG. 3 is a cross-sectional view illustrating an example of three pixels in a comparative example.

FIG. 4 is a cross-sectional view illustrating an example of three pixels in a variation of the first embodiment of the present technology.

FIG. 5 is a cross-sectional view illustrating an example of three pixels in a second embodiment of the present technology.

FIG. 6 is a cross-sectional view illustrating an example of three pixels in a first variation of the second embodiment of the present technology.

FIG. 7 is a cross-sectional view illustrating an example of three pixels in a second variation of the second embodiment of the present technology.

FIG. 8 is a cross-sectional view illustrating an example of three pixels in a third embodiment of the present technology.

FIG. 9 is a cross-sectional view illustrating an example of three pixels in a first variation of the third embodiment of the present technology.

FIG. 10 is a cross-sectional view illustrating an example of three pixels in a second variation of the third embodiment of the present technology.

FIG. 11 is a cross-sectional view illustrating an example of three pixels in a fourth embodiment of the present technology.

FIG. 12 is a cross-sectional view illustrating an example of three pixels in a variation of the fourth embodiment of the present technology.

FIG. 13 is a cross-sectional view illustrating an example of three pixels in a fifth embodiment of the present technology.

FIG. 14 is a cross-sectional view illustrating an example of three pixels in a sixth embodiment of the present technology.

FIG. 15 is a cross-sectional view illustrating an example of three pixels in a first variation of the sixth embodiment of the present technology.

FIG. 16 is a cross-sectional view illustrating an example of three pixels in a second variation of the sixth embodiment of the present technology.

FIG. 17 is a cross-sectional view illustrating an example of three pixels in a seventh embodiment of the present technology.

FIG. 18 is a cross-sectional view illustrating an example of three pixels in a variation of the seventh embodiment of the present technology.

FIG. 19 is a cross-sectional view illustrating an example of three pixels in an eighth embodiment of the present technology.

FIG. 20 is a cross-sectional view illustrating an example of three pixels in a first variation of the eighth embodiment of the present technology.

FIG. 21 is a cross-sectional view illustrating an example of three pixels in a second variation of the eighth embodiment of the present technology.

FIG. 22 is a cross-sectional view illustrating an example of three pixels in a ninth embodiment of the present technology.

FIG. 23 is a cross-sectional view illustrating an example of three pixels in a first variation of the ninth embodiment of the present technology.

FIG. 24 is a cross-sectional view illustrating an example of three pixels in a second variation of the ninth embodiment of the present technology.

FIG. 25 is a cross-sectional view illustrating an example of three pixels in a tenth embodiment of the present technology.

FIG. 26 is a cross-sectional view illustrating an example of three pixels in a first variation of the tenth embodiment of the present technology.

FIG. 27 is a cross-sectional view illustrating an example of three pixels in a second variation of the tenth embodiment of the present technology.

FIG. 28 is a cross-sectional view illustrating an example of three pixels in an eleventh embodiment of the present technology.

FIG. 29 is a cross-sectional view illustrating an example of three pixels in a variation of the eleventh embodiment of the present technology.

FIG. 30 is a cross-sectional view illustrating an example of three pixels in a twelfth embodiment of the present technology.

FIG. 31 is a cross-sectional view illustrating an example of three pixels in a variation of the twelfth embodiment of the present technology.

FIG. 32 is a cross-sectional view illustrating an example of three pixels in a thirteenth embodiment of the present technology.

FIG. 33 is a cross-sectional view illustrating an example of three pixels in a variation of the thirteenth embodiment of the present technology.

FIG. 34 is a cross-sectional view illustrating an example of three pixels in a fourteenth embodiment of the present technology.

FIG. 35 is a cross-sectional view illustrating an example of three pixels in a variation of the fourteenth embodiment of the present technology.

FIG. 36 is a block diagram illustrating a light receiving element including a pixel according to the first to fourteenth embodiments of the present technology.

FIG. 37 is a block diagram illustrating a configuration example of an embodiment of a ranging system in which the light receiving element illustrated in FIG. 36 is incorporated.

FIG. 38 is a block diagram illustrating a configuration example of a smartphone as an electronic device equipped with the ranging system illustrated in FIG. 37.

FIG. 39 is a block diagram illustrating a configuration example of an embodiment of an imaging device as an electronic device to which the present technology is applied.

### MODE FOR CARRYING OUT THE INVENTION

Hereinafter, an embodiment of the present disclosure is described with reference to the drawings. In the illustration of the drawings referred to in the following description, the same or similar portions are denoted by the same or similar reference signs, and redundant description is omitted. It should be noted that the drawings are schematic, and a relationship between a thickness and a planar dimension, a ratio of the thicknesses among devices and members and the like are different from actual ones. Therefore, specific thicknesses and dimensions should be determined in consideration of the following description. Furthermore, it goes without saying that dimensional relationships and ratios are partly different among the drawings.

In this specification, a “first conductivity type” means one of a p-type and an n-type, and a “second conductivity type” means one of the p-type and the n-type different from the “first conductivity type”. Furthermore, “n” or “p” to which “+” or “−” is added means a semiconductor region having a relatively higher or lower impurity density than that of a semiconductor region to which “+” or “−” is not added. However, even in the semiconductor regions to which the same “n” and “n” are added, it does not mean that the impurity densities of the semiconductor regions are exactly the same.

Furthermore, definition of directions such as upward and downward directions in the following description is merely the definition for convenience of description, and does not limit the technical idea of the present disclosure. For example, it goes without saying that if an object is observed while being rotated by 90°, the upward and downward directions are converted into rightward and leftward directions, and if the object is observed while being rotated by 180°, the upward and downward directions are inverted.

Note that, an effect described in this specification is illustrative only; the effect is not limited thereto and there may also be another effect.

### First Embodiment

<Entire Configuration Example of Solid-State Imaging Device>

A solid-state imaging device as a semiconductor device according to a first embodiment is applicable to, for example, a ranging sensor and the like that measures a distance by a time of flight (ToF) method. The solid-state imaging device has a photoelectric conversion function for light of a wavelength from a visible region of about 380 nm or longer and shorter than 780 nm to an infrared region of about 780 nm or longer and shorter than 2400 nm, for example.

The solid-state imaging device performs photoelectric conversion on incident light, and a plurality of pixels each including an SPAD that accumulates carriers such as electrons and holes is two-dimensionally arranged in an array to perform imaging.

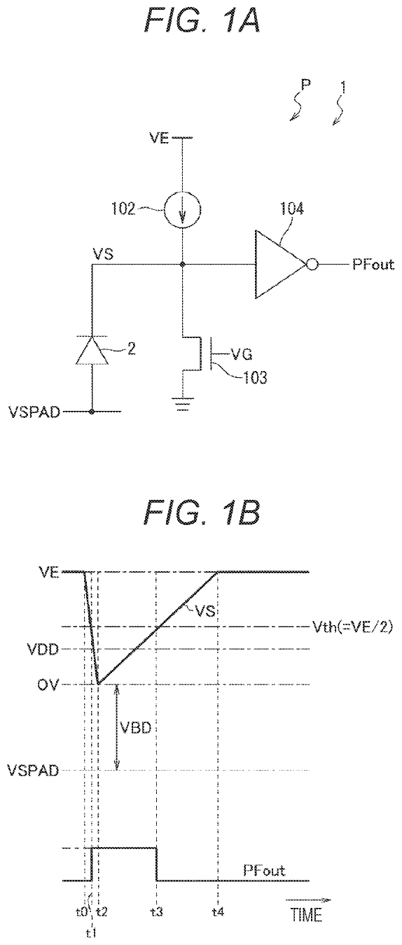

FIG. 1A illustrates a pixel circuit using the SPAD. A solid-state imaging device 1 is provided with a pixel P. The pixel P in FIG. 1A is provided with an SPAD element 2, a constant current source 102, a transistor 103, and an inverter 104.

A cathode of the SPAD element 2 is connected to the constant current source 102, and is connected to an input terminal of the inverter 104 and a drain of the transistor 103. An anode of the SPAD element 2 is connected to a power supply VSPAD.

The SPAD element 2 is a photodiode (single photon avalanche photodiode) that performs avalanche amplification on a generated electron and outputs a signal of a cathode voltage VS when incident light is incident thereon. The power supply VSPAD supplied to the anode of the SPAD element 2 is set to, for example, a negative bias (negative potential) of the same voltage as a breakdown voltage VBD of the SPAD element 2.

The constant current source 102 includes, for example, a P-type MOS transistor that operates in a saturation region, and performs passive quenching by acting as a quenching resistor. A power supply voltage VE (VE>0) is supplied to the constant current source 102. Note that, a pull-up resistor and the like may also be used for the constant current source 102 in place of the P-type MOS transistor.

In order to detect light (photon) with sufficient efficiency, a voltage (hereinafter, referred to as an excess bias) larger than the breakdown voltage VBD of the SPAD element 2 is applied to the SPAD element 2.

The drain of the transistor 103 is connected to the cathode of the SPAD element 2, the input terminal of the inverter 104, and the constant current source 102, and a source of the transistor 103 is connected to a ground (GND). A gating control signal VG is supplied from a pixel drive unit that drives the pixel P to a gate of the transistor 103.

In a case where the pixel P is an active pixel, a low (Lo) gating control signal VG is supplied from the pixel drive unit to the gate of the transistor 103. In contrast, in a case where the pixel P is a non-active pixel, a high (Hi) gating control signal VG is supplied from the pixel drive unit to the gate of the transistor 103.

The inverter 104 outputs a Hi PFout signal when the cathode voltage VS as an input signal is Lo, and outputs a Lo PFout signal when the cathode voltage VS is Hi.

Next, an operation in a case where the pixel P is the active pixel is described with reference to FIG. 1B. FIG. 1B is a graph illustrating a change in cathode voltage VS of the SPAD element 2 according to incidence of a photon and the detection signal PFout.

First, in a case where the pixel P is the active pixel, the transistor 103 is set to OFF by the Lo gating control signal VG.

At time before time t0 in FIG. 1B, since the power supply voltage VE and the power supply VSPAD are supplied to the cathode and the anode of the SPAD element 2, respectively, a reverse voltage larger than the breakdown voltage VBD is applied to the SPAD element 2, so that the SPAD element 2 is set to a Geiger mode. In this state, the cathode voltage VS of the SPAD element 2 is the same as the power supply voltage VE.

When the photon is incident on the SPAD element 2 set to the Geiger mode, avalanche multiplication occurs, and a current flows through the SPAD element 2.

Supposing that the avalanche multiplication occurs and the current flows through the SPAD element 2 at time t0, after time t0, the current flows through the SPAD element 2, so that the current also flows through the P-type MOS transistor as the constant current source 102, and a voltage drop occurs due to a resistance component of the MOS transistor.

At time t2, when the cathode voltage VS of the SPAD element 2 becomes lower than 0 V, this becomes lower than the breakdown voltage VBD, so that avalanche amplification stops. Here, an operation in which the current generated by the avalanche amplification flows through the constant current source 102 to generate the voltage drop, and the cathode voltage VS becomes lower than the breakdown voltage VBD along with the generated voltage drop, thereby stopping the avalanche amplification is the quenching operation.

When the avalanche amplification stops, the current flowing through the constant current source 102 (P-type MOS transistor) gradually decreases, and at time t4, the cathode voltage VS returns to the original power supply voltage VE again, and it enters a state in which a next new photon may be detected (recharge operation).

The inverter 104 outputs the low (Lo) PFout signal when the cathode voltage VS, which is an input voltage, is equal to or higher than a predetermined threshold voltage Vth (=VE/2), and outputs the Hi PFout signal when the cathode voltage VS is lower than the predetermined threshold voltage Vth. In the example in FIG. 1B, the high (Hi) PFout signal is output during a period from time t1 to time t3.

Note that, in a case where the pixel P is the non-active pixel, the Hi gating control signal VG is supplied from the pixel drive unit to the gate of the transistor 103, and the transistor 103 is turned on. Therefore, the cathode voltage VS of the SPAD element 2 becomes 0 V (GND), and an anode-cathode voltage of the SPAD element 2 becomes equal to or lower than the breakdown voltage VBD, so that no reaction occurs even if the photon enters the SPAD element 2.

<Configuration of Pixel>

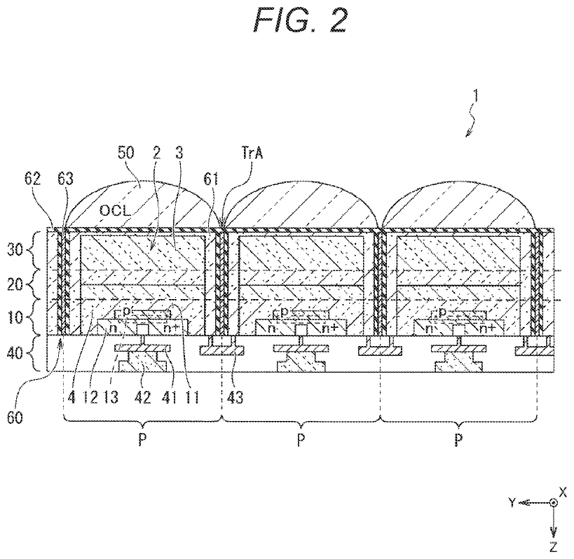

FIG. 2 is a cross-sectional view of three pixels P. In FIG. 2, the solid-state imaging device 1 is exemplified by a back-illuminated type. Hereinafter, a surface on a light incident surface side (upper side in FIG. 2) of each member of the solid-state imaging device 1 is referred to as a “back surface”, and a surface on a side (lower side in FIG. 2) opposite to the light incident surface side of each member of the solid-state imaging device 1 is referred to as a “front surface”. Furthermore, since the three pixels P have the same structure, the pixel P on a left side in FIG. 2 is representatively described.

As illustrated in FIG. 2, in the solid-state imaging device 1, a substrate 10, a transitional layer 20, a stacked material portion 30, which is a stacked structure by crystal growth, a p-type well region 61, and an interlayer film 62 are stacked in this order. On the back surface of the interlayer film 62, an on-chip lens 50 is stacked for each pixel P. Moreover, a wiring layer 40 is stacked on the front surface of the substrate 10.

The substrate 10 is formed by using, for example, a semiconductor substrate including single crystal silicon. In the substrate 10, concentration of p-type (first conductivity type) or n-type (second conductivity type) impurities is controlled, and the SPAD element 2 is formed for each pixel P.

In the wiring layer 40, wiring for supplying the voltage to be applied to the SPAD element 2, wiring for extracting the electrons (carriers) generated in the SPAD element 2 from the substrate 10 and the like are formed.

The pixel P includes the SPAD element 2 and a pixel isolation unit 60. A plurality of pixels P is arranged in each of an X direction and a Y direction orthogonal to each other via the pixel isolation unit 60. The pixel P is electrically and optically isolated from an adjacent pixel P by the pixel isolation unit 60.

The pixel isolation unit 60 is provided with a trench TrA (hereinafter, referred to as a full trench TrA) obtained by sandwiching a metal film 63 from both sides by the interlayer films 62 in a direction orthogonal to a thickness direction of the substrate 10 (Z direction). Then, the pixel isolation unit 60 provided with the full trench TrA extends from the front surface of the substrate 10 to the back surface of the stacked material portion 30. The metal film 63 is formed by using a metallic film that reflects light, for example, a tungsten (W) film. The interlayer film 62 is formed by using an insulating film, for example, a silicon oxide film.

The SPAD element 2 includes a light absorption unit 3 provided in the stacked material portion 30 and the transitional layer 20, and a Geiger multiplication unit 4 provided in the substrate 10 and the transitional layer 20. The light absorption unit 3 is a photoelectric conversion unit that absorbs light incident from the on-chip lens 50 via the interlayer film 62 and the p-type well region 61 to generate the electron (carrier). Then, the light absorption unit 3 transfers the electron generated by the photoelectric conversion to the Geiger multiplication unit 4 by an electric field.

The Geiger multiplication unit 4 performs the avalanche multiplication on the electron transferred from the light absorption unit 3. The Geiger multiplication unit 4 includes a p-type first electrode region 11 provided on the front surface side of the substrate 10 and an n-type second electrode region 12 provided at a position shallower than that of the p-type first electrode region 11 with a pn junction with the p-type first electrode region 11, and an avalanche multiplication region 13 is formed on an interface of the pn junction.

In the substrate 10, the p-type first electrode region 11 includes a p-type semiconductor region having high impurity concentration in the Geiger multiplication unit 4, and the n-type second electrode region 12 includes an n-type semiconductor region having high impurity concentration in the Geiger multiplication unit 4. The avalanche multiplication region 13 is a high electric field region (depletion layer) formed on the interface of the pn junction between the p-type first electrode region 11 and the n-type second electrode region 12 by a negative voltage higher than the breakdown voltage applied to the n-type second electrode region 12, and multiplies the electron generated by one photon by the light absorption unit 3.

The p-type well region 61 is provided along a wall surface of the pixel isolation unit 60 and the back surface of the stacked material portion 30. The p-type well region 61 includes a p-type semiconductor region having higher impurity concentration than that of the p-type first electrode region 11, and accumulates holes as the carriers. The p-type well region 61 is electrically connected to an anode 43 formed in the wiring layer 40, and enables bias adjustment. Therefore, hole concentration of the p-type well region 61 is enhanced and pinning is strengthened, so that generation of a dark current may be suppressed, for example.

The wiring layer 40 is formed on the front surface side of the substrate 10 and includes wiring 41, a cathode 42, and the anode 43. The cathode 42 includes an n-type semiconductor region having higher impurity concentration than that of the n-type second electrode region 12, and is electrically connected to the n-type second electrode region 12 via the wiring 41.

Therefore, in the pixel P, a negative voltage higher than the breakdown voltage applied to the n-type second electrode region 12 may be supplied from a logic circuit (not illustrated) to the cathode 42. Furthermore, in the pixel P, the bias adjustment on the p-type well region 61 via the anode 43 may be enabled.

In the solid-state imaging device 1 having the above-described configuration, the light is applied, the applied light is transmitted through the on-chip lens 50, and the transmitted light is photoelectrically converted by the SPAD element 2, so that the electron is generated. Then, the generated electron is output to the inverter 104 by the wiring 41 in the wiring layer 40.

### Comparative Example

By the way, since silicon (Si) is conventionally used in a substrate, sensitivity in an infrared (IR) region is low, and it is necessary to make Si thick in order to improve PDE.

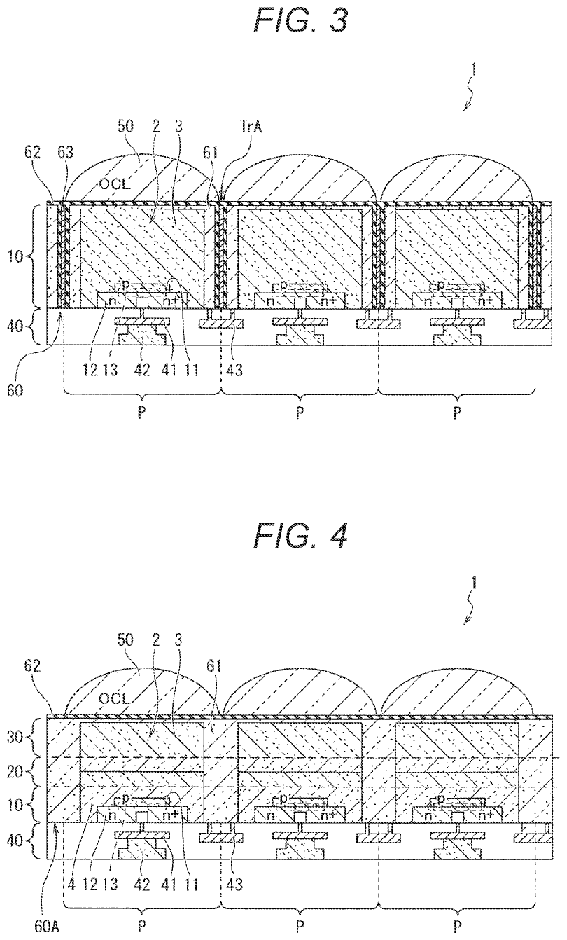

FIG. 3 is a cross-sectional view illustrating an example of a solid-state imaging device 1 in a comparative example. In FIG. 3, the same portion as that in FIG. 2 described above is denoted by the same reference sign, and detailed description thereof is omitted.

In the comparative example, when a substrate 10 including Si is made thick, time for a photoelectrically converted electron to reach a multiplication region becomes long, and there is a concern about deterioration in jitter characteristic in a case where this is used as laser imaging detection and ranging (LIDAR).

<Countermeasure by First Embodiment>

With reference to FIG. 2 again, in the first embodiment of the present technology, the stacked material portion 30 including a semiconductor material different from a semiconductor material of the substrate 10 is stacked on the surface on the light incident side of the substrate 10, so that absorption efficiency of IR light is improved and PDE is improved.

As the semiconductor material included in the stacked material portion 30, silicon germanium (SiGe) crystal growth of which with respect to silicon is possible, germanium (Ge), gallium arsenide (GaAs), indium arsenide (InAs), indium gallium arsenide (InGaAs), aluminum gallium arsenide (AlGaAs), cadmium telluride (CdTe), cadmium sulfur (CdS) and the like are used. Since these semiconductor materials do not lattice-match with silicon, it is necessary to interpose the transitional layer 20 between the substrate 10 and the stacked material portion 30.

For example, SiGe, Ge, InGaAs and the like are narrow bandgap semiconductors having bandgap energy smaller than that of silicon, and have light absorption sensitivity in an infrared (IR) light region on a longer wavelength side than a visible light region.

Note that, also in a case where gallium arsenide (GaAs) and indium phosphide (InP) are used in the substrate 10, as is the case with silicon, silicon germanium (SiGe), germanium (Ge), gallium arsenide (GaAs), indium arsenide (InAs), indium gallium arsenide (InGaAs), aluminum gallium arsenide (AlGaAs), cadmium telluride (CdTe), cadmium sulfur (CdS) and the like are used in the stacked material portion 30.

### Action and Effect by First Embodiment

As described above, according to the first embodiment, by stacking the stacked material portion 30 including the semiconductor material different from silicon used in the substrate 10 on the surface on the light incident side of the substrate 10 via the transitional layer 20, it is possible to improve the absorption efficiency of the IR light and improve the PDE, and it is possible to improve a jitter characteristic by making the pixel P thinner than the pixel P including only a silicon substrate.

Furthermore, according to the first embodiment, by providing the pixel isolation unit 60 with the full trench TrA that insulates and isolates a plurality of adjacent pixels P from each other, it is possible to suppress crosstalk to the adjacent pixel P.

### Variation of First Embodiment

FIG. 4 is a cross-sectional view illustrating an example of a solid-state imaging device 1 in a variation of the first embodiment of the present technology. In FIG. 4, the same portion as that in FIG. 2 described above is denoted by the same reference sign, and detailed description thereof is omitted.

As illustrated in FIG. 4, a full trench TrA obtained by sandwiching a metal film 63 from both sides by interlayer films 62 is not provided on a pixel isolation unit 60A in the variation.

According to such variation of the first embodiment also, it is possible to improve absorption efficiency of IR light and improve PDE, and it is possible to improve a jitter characteristic by making a pixel P thinner than the pixel P including only a silicon substrate.

### Second Embodiment

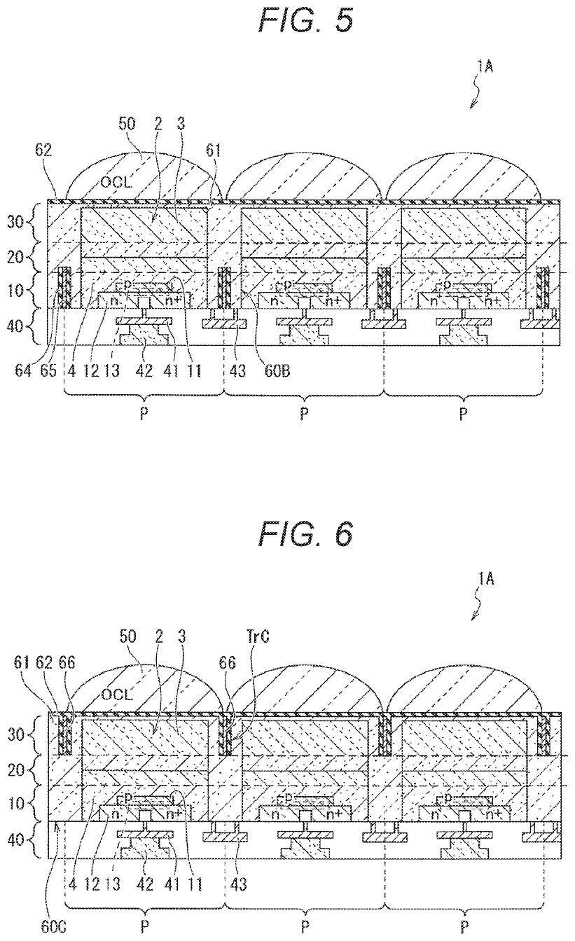

FIG. 5 is a cross-sectional view illustrating an example of a solid-state imaging device 1A in a second embodiment of the present technology. In FIG. 5, the same portion as that in FIG. 2 described above is denoted by the same reference sign, and detailed description thereof is omitted.

As illustrated in FIG. 5, a pixel isolation unit 60B in the second embodiment is provided with a trench TrB (hereinafter, referred to as a front surface trench TrB) only on a substrate 10 side. The front surface trench TrB is obtained by sandwiching a metal film 65 from both sides by insulating films 64 in a direction orthogonal to a thickness direction of the substrate 10 (Z direction). Then, the front surface trench TrB extends from a front surface of the substrate 10 to a back surface of the substrate 10.

### Action and Effect by Second Embodiment

As described above, according to the second embodiment, the solid-state imaging device 1A may be easily manufactured by processing only the substrate 10 to form the pixel isolation unit 60B.

### First Variation of Second Embodiment

FIG. 6 is a cross-sectional view illustrating an example of a solid-state imaging device 1A in a first variation of the second embodiment of the present technology. In FIG. 6, the same portion as that in FIG. 2 described above is denoted by the same reference sign, and detailed description thereof is omitted.

As illustrated in FIG. 6, a pixel isolation unit 60C in the first variation of the second embodiment is provided with a trench TrC (hereinafter, referred to as a back surface trench TrC) only on a stacked material portion 30 side. The back surface trench TrC is obtained by sandwiching a metal film 66 from both sides by interlayer films 62 in a direction orthogonal to a thickness direction of the stacked material portion 30 (Z direction). Then, the back surface trench TrC extends from a back surface of the stacked material portion 30 to a front surface of the stacked material portion 30.

### Action and Effect by First Variation of Second Embodiment

As described above, according to the first variation of the second embodiment, the solid-state imaging device 1A may be easily manufactured by processing only the stacked material portion 30 to form the pixel isolation unit 60B.

### Second Variation of Second Embodiment

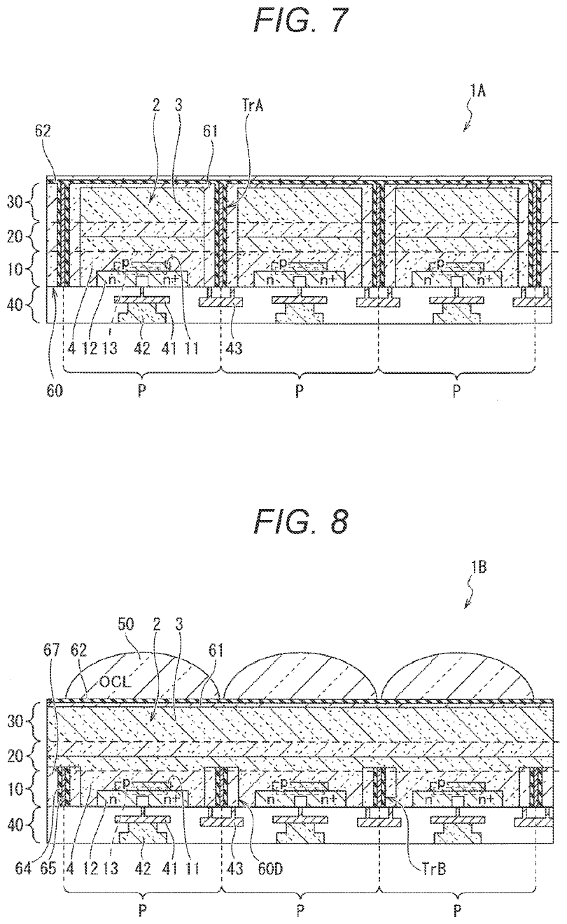

FIG. 7 is a cross-sectional view illustrating an example of a solid-state imaging device 1A in a second variation of the second embodiment of the present technology. In FIG. 7, the same portion as that in FIG. 2 described above is denoted by the same reference sign, and detailed description thereof is omitted.

As illustrated in FIG. 7, the solid-state imaging device 1A in the second variation of the second embodiment has a structure in which an on-chip lens 50 is not provided.

### Action and Effect by Second Variation of Second Embodiment

As described above, according to the second variation of the second embodiment, as is the case with the first embodiment described above, by processing a substrate 10, a transitional layer 20, and a stacked material portion 30 to form a pixel isolation unit 60, the solid-state imaging device 1A may be easily manufactured, and by providing the pixel isolation unit 60 with a full trench TrA that insulates and isolates a plurality of adjacent pixels P from each other, crosstalk to the adjacent pixels P may be suppressed.

### Third Embodiment

FIG. 8 is a cross-sectional view illustrating an example of a solid-state imaging device 1B in a third embodiment of the present technology. In FIG. 8, the same portion as that in FIG. 2 described above is denoted by the same reference sign, and detailed description thereof is omitted.

As illustrated in FIG. 8, a pixel isolation unit 60D in the third embodiment extends from a front surface of a substrate 10 to a back surface of the substrate 10. The pixel isolation unit 60D is provided with a front surface trench TrB obtained by sandwiching a metal film 65 from both sides by insulating films 64 in a direction orthogonal to a thickness direction of the substrate 10 (Z direction). A p-type well region 67 is provided on a wall surface of the pixel isolation unit 60D.

A stacked material portion 30 in the third embodiment is an n-type semiconductor region.

### Action and Effect by Third Embodiment

As described above, according to the third embodiment, action and effect similar to those of the second embodiment described above may be obtained, and a region capable of absorbing light may be expanded by not making the stacked material portion 30 p-type.

### First Variation of Third Embodiment

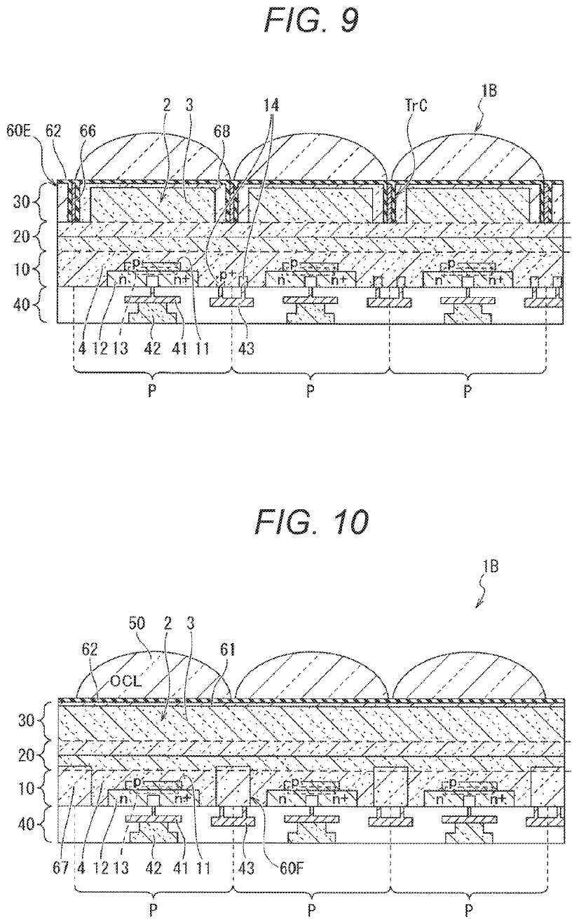

FIG. 9 is a cross-sectional view illustrating an example of a solid-state imaging device 1B in a first variation of the third embodiment of the present technology. In FIG. 9, the same portion as that in FIG. 2 described above is denoted by the same reference sign, and detailed description thereof is omitted.

As illustrated in FIG. 9, a pixel isolation unit 60E in the first variation of the third embodiment is provided with a trench TrC (hereinafter, referred to as a back surface trench TrC) only on a stacked material portion 30 side. The back surface trench TrC is obtained by sandwiching a metal film 66 from both sides by interlayer films 62 in a direction orthogonal to a thickness direction of the stacked material portion 30 (Z direction). Then, the back surface trench TrC extends from a back surface of the stacked material portion 30 to a front surface of the stacked material portion 30.

A p-type well region 68 is provided on a wall surface of the pixel isolation unit 60E. A p-type well region 14 electrically connected to an anode 43 of a wiring layer 40 is provided on a front surface side of a substrate 10.

### Action and Effect by First Variation of Third Embodiment

As described above, according to the first variation of the third embodiment, action and effect similar to those of the first variation of the second embodiment described above may be obtained, and color mixing on a light incident side may be suppressed.

### Second Variation of Third Embodiment

FIG. 10 is a cross-sectional view illustrating an example of a solid-state imaging device 1B in a second variation of the third embodiment of the present technology. In FIG. 10, the same portion as that in FIG. 8 described above is denoted by the same reference sign, and detailed description thereof is omitted.

As illustrated in FIG. 10, in a pixel isolation unit 60F in the second variation, a trench obtained by sandwiching a metal film 65 from both sides by insulating films 64 is not provided, and only a p-type well region 67 is provided.

According to such second variation of the third embodiment also, action and effect similar to those of the third embodiment described above may be obtained.

### Fourth Embodiment

FIG. 11 is a cross-sectional view illustrating an example of a solid-state imaging device 1C in a fourth embodiment of the present technology. In FIG. 11, the same portion as that in FIG. 2 described above is denoted by the same reference sign, and detailed description thereof is omitted.

As illustrated in FIG. 11, in the solid-state imaging device 1C in the fourth embodiment, an antireflection unit (RIG) 69 having a moth-eye structure is provided on a back surface side of a stacked material portion 30. The RIG 69 prevents reflection of incident light.

### Action and Effect by Fourth Embodiment

As described above, according to the fourth embodiment, by providing the RIG 69, it is possible to further improve quantum efficiency and to suppress flare by reducing surface reflection.

### Variation of Fourth Embodiment

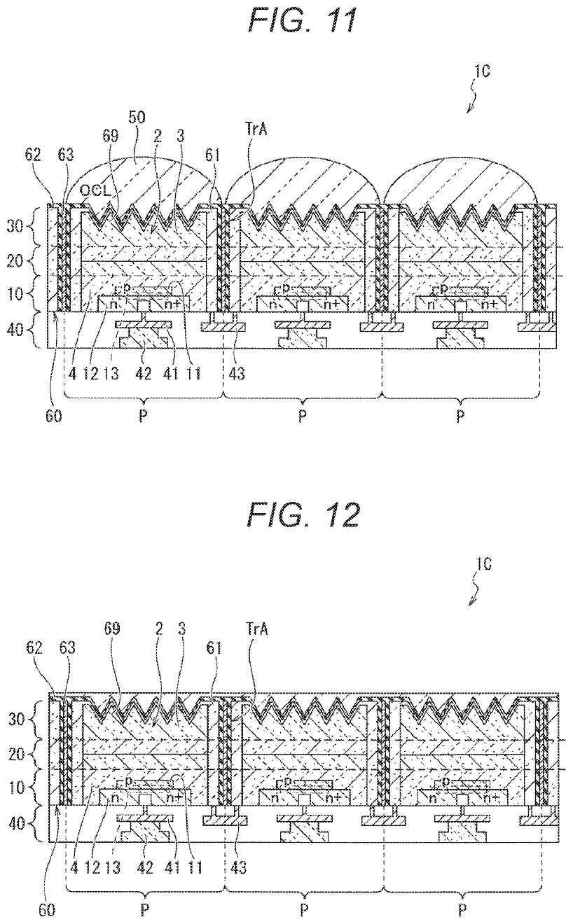

FIG. 12 is a cross-sectional view illustrating an example of a solid-state imaging device 1C in a variation of the fourth embodiment of the present technology. In FIG. 12, the same portion as that in FIG. 11 described above is denoted by the same reference sign, and detailed description thereof is omitted.

As illustrated in FIG. 12, the solid-state imaging device 1C in the variation of the fourth embodiment has a structure in which an on-chip lens 50 provided for each pixel P is eliminated.

### Action and Effect by Variation of Fourth Embodiment

As described above, according to a first variation of the fourth embodiment, by eliminating the on-chip lens 50, it is possible to further reduce surface reflection and suppress flare.

### Fifth Embodiment

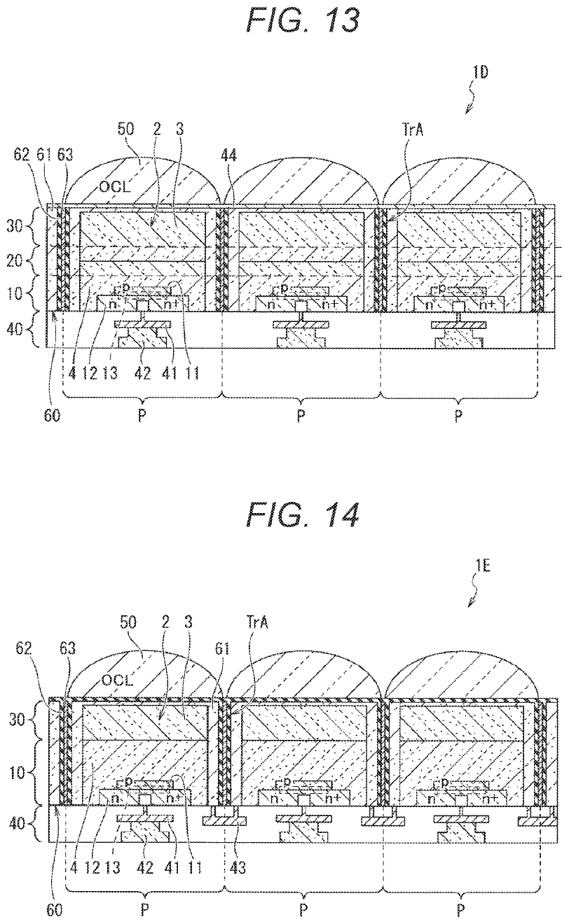

FIG. 13 is a cross-sectional view illustrating an example of a solid-state imaging device 1D in a fifth embodiment of the present technology. In FIG. 13, the same portion as that in FIG. 2 described above is denoted by the same reference sign, and detailed description thereof is omitted.

As illustrated in FIG. 13, in the solid-state imaging device 1D in the fifth embodiment, a transparent electrode 44 serving as an anode is provided between a p-type well region 61 and an on-chip lens 50.

The p-type well region 61 is electrically connected to the transparent electrode 44 and enables bias adjustment. This makes it possible to make a transfer electric field on a back surface high.

Therefore, in the pixel P, a negative voltage higher than the breakdown voltage applied to the n-type second electrode region 12 may be supplied from a logic circuit (not illustrated) to the cathode 42. Furthermore, in the pixel P, the bias adjustment on the p-type well region 61 via the transparent electrode 44 may be enabled.

### Action and Effect by Fifth Embodiment

As described above, according to the fifth embodiment, an anode on the front surface becomes unnecessary by providing the transparent electrode 44, so that a multiplication region may be enlarged, and multiplication probability may be improved. Furthermore, by making the transfer electric field on the back surface high, further improvement in jitter characteristic may be expected.

### Sixth Embodiment

FIG. 14 is a cross-sectional view illustrating an example of a solid-state imaging device 1E in a sixth embodiment of the present technology. In FIG. 14, the same portion as that in FIG. 2 described above is denoted by the same reference sign, and detailed description thereof is omitted.

As illustrated in FIG. 14, in the solid-state imaging device 1E in the sixth embodiment, a substrate 10, a stacked material portion 30, a p-type well region 61, and an interlayer film 62 are stacked in this order. In the stacked material portion 30, a semiconductor material by crystal growth that lattice-matches with the substrate 10 is used. For example, in a case where gallium arsenide (GaAs) is used in the substrate 10, germanium (Ge) or gallium arsenide (GaAs) is used in the stacked material portion 30. Furthermore, for example, in a case where indium phosphide (InP) is used in the substrate 10, indium gallium arsenide (InGaAs) is used in the stacked material portion 30.

### Action and Effect by Sixth Embodiment

As described above, according to the sixth embodiment, a defect on a junction interface between the substrate 10 and the stacked material portion 30 may be prevented by using the semiconductor material that lattice-matches with the substrate 10 in the stacked material portion 30.

### First Variation of Sixth Embodiment

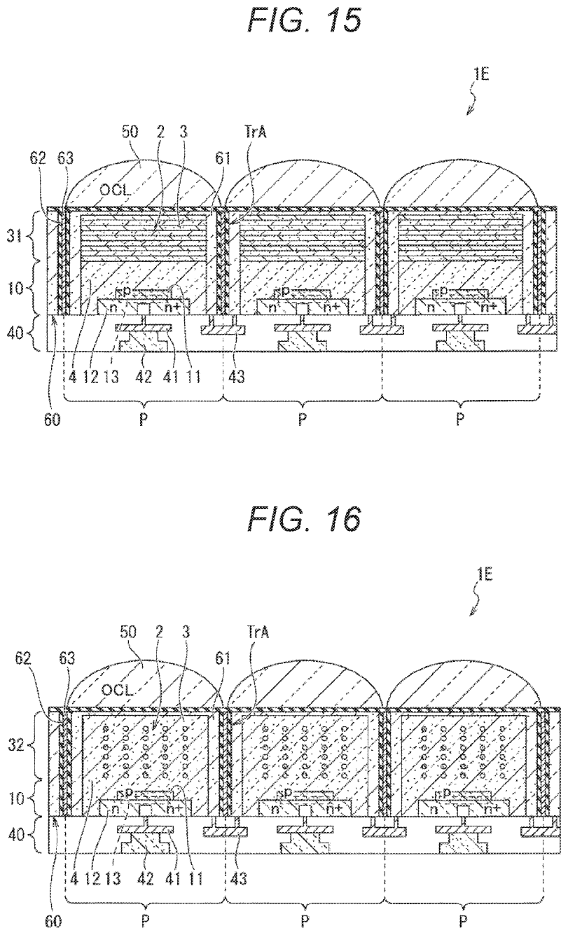

FIG. 15 is a cross-sectional view illustrating an example of a solid-state imaging device 1E in a first variation of the sixth embodiment of the present technology. In FIG. 15, the same portion as that in FIG. 14 described above is denoted by the same reference sign, and detailed description thereof is omitted.

As illustrated in FIG. 15, a stacked material portion 31 in the first variation of the sixth embodiment has a multiple stacked (quantum well) type structure.

### Action and Effect by First Variation of Sixth Embodiment

According to the first variation of the sixth embodiment, by controlling a bandgap by the stacked material portion 31 having the quantum well type structure to improve absorption efficiency of IR light, a specific wavelength may be efficiently absorbed by a subband of the quantum well type structure.

### Second Variation of Sixth Embodiment

FIG. 16 is a cross-sectional view illustrating an example of a solid-state imaging device 1E in a second variation of the sixth embodiment of the present technology. In FIG. 16, the same portion as that in FIG. 14 described above is denoted by the same reference sign, and detailed description thereof is omitted.

As illustrated in FIG. 16, a stacked material portion 32 in the second variation of the sixth embodiment has a quantum dot type structure.

### Action and Effect by Second Variation of Sixth Embodiment

According to the second variation of the sixth embodiment, by controlling a bandgap by the stacked material portion 32 having the quantum dot type structure to improve absorption efficiency of IR light, a specific wavelength may be efficiently absorbed by a subband of the quantum dot type structure.

### Seventh Embodiment

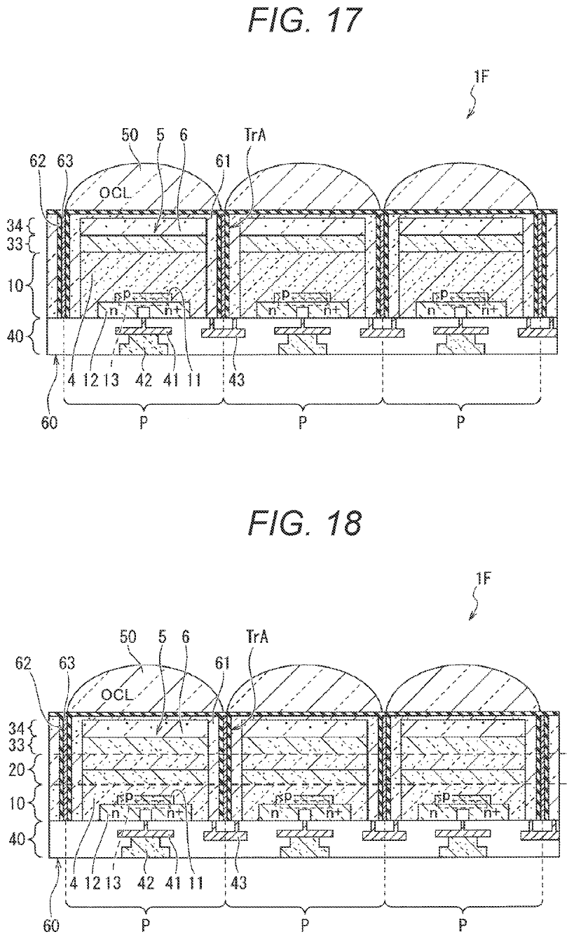

FIG. 17 is a cross-sectional view illustrating an example of a solid-state imaging device 1F in a seventh embodiment of the present technology. In FIG. 17, the same portion as that in FIG. 2 described above is denoted by the same reference sign, and detailed description thereof is omitted.

As illustrated in FIG. 17, in the solid-state imaging device 1F in the seventh embodiment, a substrate 10, an n-type stacked material portion 33, a p-type stacked material portion 34, a p-type well region 61, and an interlayer film 62 are stacked in this order.

An SPAD element 5 is formed for each pixel P. The SPAD element 5 includes a linear multiplication unit 6 provided in the n-type stacked material portion 33 and the p-type stacked material portion 34, and a Geiger multiplication unit 4 provided in the substrate 10. The linear multiplication unit 6 absorbs light incident from an on-chip lens 50 via the interlayer film 62 and the p-type well region 61 to generate an electron (carrier), and performs linear multiplication on the electron. Then, the linear multiplication unit 6 transfers the electrons subjected to the linear multiplication to the Geiger multiplication unit 4 by an electric field.

The linear multiplication unit 6 forms a pn junction with the n-type stacked material portion 33 and the p-type stacked material portion 34, and forms a linear multiplication region on an interface of the pn junction. In the linear multiplication region, the electron generated by one photon is subjected to the linear multiplication by a slightly higher negative voltage near a breakdown voltage applied to the n-type stacked material portion 33.

### Action and Effect by Seventh Embodiment

As described above, according to the seventh embodiment, higher PDE may be achieved by adopting a two-stage multiplication structure in which the linear multiplication is performed by the linear multiplication unit 6 without depending on Geiger multiplication only by the Geiger multiplication unit 4.

### Variation of Seventh Embodiment

FIG. 18 is a cross-sectional view illustrating an example of a solid-state imaging device 1E in a variation of the seventh embodiment of the present technology. In FIG. 18, the same portion as that in FIG. 17 described above is denoted by the same reference sign, and detailed description thereof is omitted.

As illustrated in FIG. 18, in the variation of the seventh embodiment, a transitional layer 20 is interposed between a substrate 10 and an n-type stacked material portion 33.

### Action and Effect by Variation of Seventh Embodiment

Even with the variation of the seventh embodiment, action and effect similar to those of the seventh embodiment described above may be obtained, and the substrate 10 and the n-type stacked material portion 33 may be stacked also by using a semiconductor material that does not lattice-match.

### Eighth Embodiment

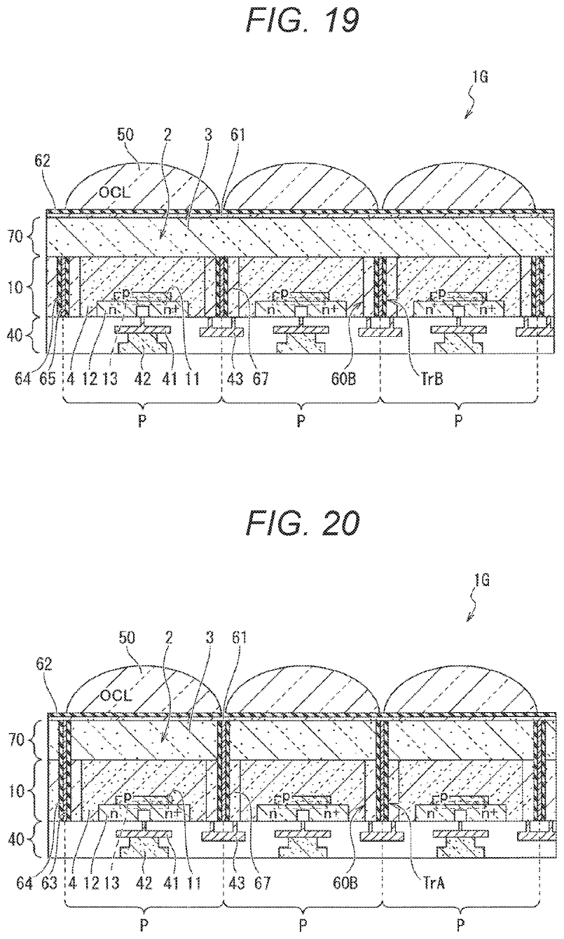

FIG. 19 is a cross-sectional view illustrating an example of a solid-state imaging device 1G in an eighth embodiment of the present technology. In FIG. 19, the same portion as that in FIG. 5 described above is denoted by the same reference sign, and detailed description thereof is omitted.

As illustrated in FIG. 19, in the solid-state imaging device 1G in the eighth embodiment, a substrate 10, a stacked material portion 70, a p-type well region 61, and an interlayer film 62 are stacked in this order. In the stacked material portion 70, a semiconductor material by a nano crystal film that lattice-matches with the substrate 10 is used. For example, as the semiconductor material included in the stacked material portion 70, palladium sulfur (PdS), CsPbI3, CuGaSe2, CuInSe2 and the like are used with respect to silicon. This is similar for gallium arsenide (GaAs) and indium phosphide (InP).

A pixel isolation unit 60B in the eighth embodiment is provided with a trench TrB (hereinafter, referred to as a front surface trench TrB) only on the substrate 10 side. The front surface trench TrB is obtained by sandwiching a metal film 65 from both sides by insulating films 64 in a direction orthogonal to a thickness direction of the substrate 10 (Z direction). Then, the front surface trench TrB extends from a front surface of the substrate 10 to a back surface of the substrate 10.

### Action and Effect by Eighth Embodiment

As described above, according to the eighth embodiment, by using the nano crystal in the stacked material portion 70, absorption efficiency not lower than that of a normal crystal may be obtained. Furthermore, the solid-state imaging device 1G may be easily manufactured by processing only the substrate 10 to form the pixel isolation unit 60B.

### First Variation of Eighth Embodiment

FIG. 20 is a cross-sectional view illustrating an example of a solid-state imaging device 1G in a first variation of the eighth embodiment of the present technology. In FIG. 20, the same portion as that in FIG. 19 described above is denoted by the same reference sign, and detailed description thereof is omitted.

As illustrated in FIG. 20, a pixel isolation unit 60B in the first variation of the eighth embodiment is provided with a full trench TrA. The full trench TrA is obtained by sandwiching a metal film 63 from both sides by insulating films 64 in a direction orthogonal to a thickness direction of a substrate 10 (Z direction). Then, the full trench TrA extends from a front surface of the substrate 10 to a back surface of a stacked material portion 70.

### Action and Effect by First Variation of Eighth Embodiment

As described above, according to the first variation of the eighth embodiment, light leakage to an adjacent pixel P may be prevented.

### Second Variation of Eighth Embodiment

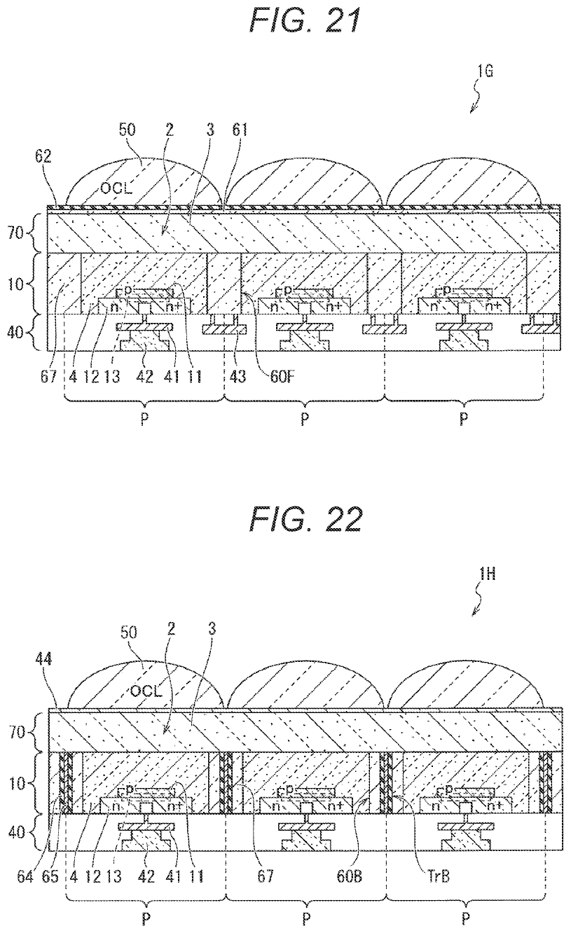

FIG. 21 is a cross-sectional view illustrating an example of a solid-state imaging device 1G in a second variation of the eighth embodiment of the present technology. In FIG. 21, the same portion as that in FIG. 19 described above is denoted by the same reference sign, and detailed description thereof is omitted.

As illustrated in FIG. 21, a pixel isolation unit 60F in the second variation is not provided with a full trench TrA.

According to such second variation of the eighth embodiment also, action and effect similar to those of the eighth embodiment described above may be obtained.

### Ninth Embodiment

FIG. 22 is a cross-sectional view illustrating an example of a solid-state imaging device 1H in a ninth embodiment of the present technology. In FIG. 22, the same portion as that in FIG. 19 described above is denoted by the same reference sign, and detailed description thereof is omitted.

As illustrated in FIG. 22, in the solid-state imaging device 1H in the ninth embodiment, a transparent electrode 44 serving as an anode is provided between a stacked material portion 70 and an on-chip lens 50.

The stacked material portion 70 is electrically connected to the transparent electrode 44 and enables bias adjustment. This makes it possible to make a transfer electric field on a back surface high.

Therefore, in the pixel P, a negative voltage higher than the breakdown voltage applied to the n-type second electrode region 12 may be supplied from a logic circuit (not illustrated) to the cathode 42. Furthermore, in the pixel P, the bias adjustment on the stacked material portion 70 via the transparent electrode 44 may be enabled.

### Action and Effect by Ninth Embodiment

As described above, according to the ninth embodiment, an anode on a front surface becomes unnecessary by providing the transparent electrode 44, so that a multiplication region may be enlarged, and multiplication probability may be improved. Furthermore, by making the transfer electric field on the back surface high, further improvement in jitter characteristic may be expected.

### First Variation of Ninth Embodiment

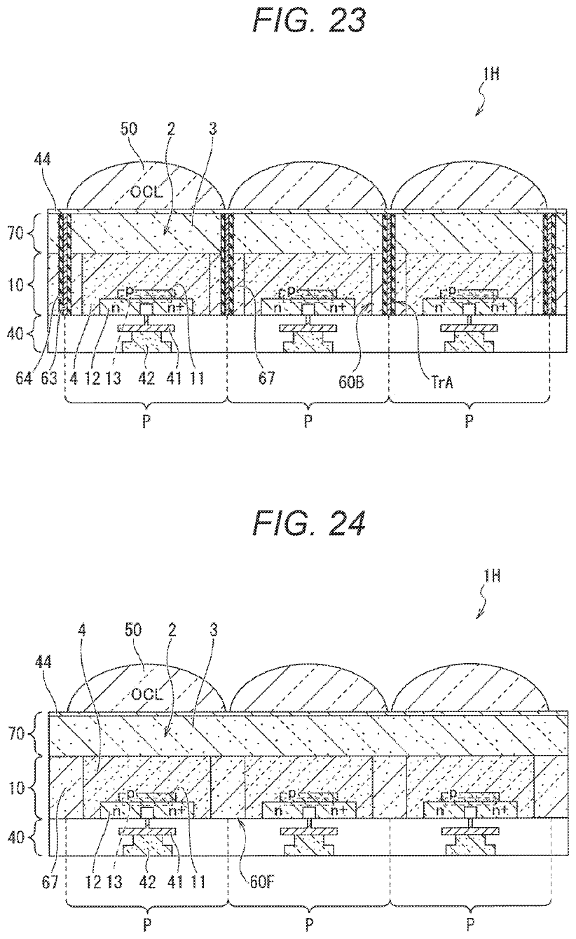

FIG. 23 is a cross-sectional view illustrating an example of a solid-state imaging device 1H in a first variation of the ninth embodiment of the present technology. In FIG. 23, the same portion as that in FIG. 22 described above is denoted by the same reference sign, and detailed description thereof is omitted.

As illustrated in FIG. 23, a pixel isolation unit 60B in the first variation of the ninth embodiment is provided with a full trench TrA. The full trench TrA is obtained by sandwiching a metal film 63 from both sides by insulating films 64 in a direction orthogonal to a thickness direction of a substrate 10 (Z direction). Then, the full trench TrA extends from a front surface of the substrate 10 to a back surface of a stacked material portion 70.

### Action and Effect by First Variation of Ninth Embodiment

As described above, according to the first variation of the ninth embodiment, action and effect similar to those of the ninth embodiment described above may be obtained.

### Second Variation of Ninth Embodiment

FIG. 24 is a cross-sectional view illustrating an example of a solid-state imaging device 1H in a second variation of the ninth embodiment of the present technology. In FIG. 24, the same portion as that in FIG. 22 described above is denoted by the same reference sign, and detailed description thereof is omitted.

As illustrated in FIG. 24, a pixel isolation unit 60F in the second variation is not provided with a full trench TrA.

According to such second variation of the ninth embodiment also, action and effect similar to those of the ninth embodiment described above may be obtained.

### Tenth Embodiment

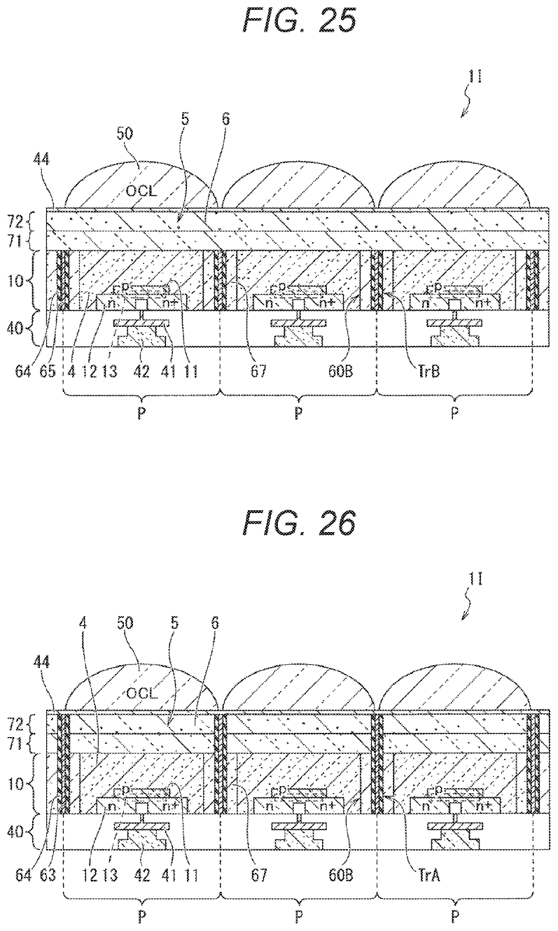

FIG. 25 is a cross-sectional view illustrating an example of a solid-state imaging device 1I in a tenth embodiment of the present technology. In FIG. 25, the same portion as that in FIG. 22 described above is denoted by the same reference sign, and detailed description thereof is omitted.

As illustrated in FIG. 25, in the solid-state imaging device 1I in the tenth embodiment, a substrate 10, an n-type stacked material portion 71, a p-type stacked material portion 72, and a transparent electrode 44 are stacked in this order.

An SPAD element 5 is formed for each pixel P. The SPAD element 5 includes a linear multiplication unit 6 provided in the n-type stacked material portion 71 and the p-type stacked material portion 72, and a Geiger multiplication unit 4 provided in the substrate 10. The linear multiplication unit 6 absorbs light incident from an on-chip lens 50 via the transparent electrode 44 to generate an electron (carrier), and performs linear multiplication on the electron. Then, the linear multiplication unit 6 transfers the electrons subjected to the linear multiplication to the Geiger multiplication unit 4 by an electric field.

The linear multiplication unit 6 forms a pn junction with the n-type stacked material portion 71 and the p-type stacked material portion 72, and forms a linear multiplication region on an interface of the pn junction. In the linear multiplication region, the electron generated by one photon is subjected to the linear multiplication by a slightly higher negative voltage near a breakdown voltage applied to the n-type stacked material portion 71.

### Action and Effect by Tenth Embodiment

As described above, according to the tenth embodiment, action and effect similar to those in the ninth embodiment described above may be obtained, and higher PDE may be achieved by adopting a two-stage multiplication structure in which the linear multiplication is performed by the linear multiplication unit 6 without depending on Geiger multiplication only by the Geiger multiplication unit 4.

### First Variation of Tenth Embodiment

FIG. 26 is a cross-sectional view illustrating an example of a solid-state imaging device 1I in a first variation of the tenth embodiment of the present technology. In FIG. 26, the same portion as that in FIG. 25 described above is denoted by the same reference sign, and detailed description thereof is omitted.

As illustrated in FIG. 26, a pixel isolation unit 60B in the first variation of the tenth embodiment is provided with a full trench TrA. The full trench TrA is obtained by sandwiching a metal film 63 from both sides by insulating films 64 in a direction orthogonal to a thickness direction of a substrate 10 (Z direction). Then, the full trench TrA extends from a front surface of the substrate 10 to a back surface of the stacked material portion 30.

### Action and Effect by First Variation of Tenth Embodiment

As described above, according to the first variation of the tenth embodiment, action and effect similar to those of the tenth embodiment described above may be obtained.

### Second Variation of Tenth Embodiment

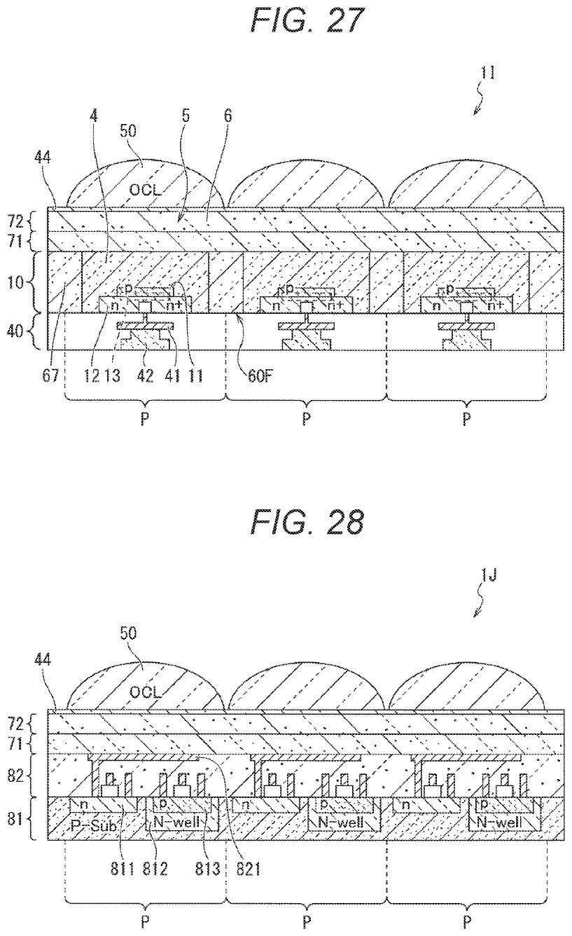

FIG. 27 is a cross-sectional view illustrating an example of a solid-state imaging device 1I in a second variation of the tenth embodiment of the present technology. In FIG. 27, the same portion as that in FIG. 25 described above is denoted by the same reference sign, and detailed description thereof is omitted.

As illustrated in FIG. 27, a pixel isolation unit 60F in the second variation is not provided with a full trench TrA.

According to such second variation of the tenth embodiment also, action and effect similar to those of the tenth embodiment described above may be obtained.

### Eleventh Embodiment

In an eleventh embodiment of the present technology, copper (Cu)-copper (Cu) junction of a readout circuit formed for each pixel becomes not necessary, and a manufacturing cost is reduced.

FIG. 28 is a cross-sectional view illustrating an example of a solid-state imaging device 1J in an eleventh embodiment of the present technology. In FIG. 28, the same portion as that in FIG. 25 described above is denoted by the same reference sign, and detailed description thereof is omitted.

As illustrated in FIG. 28, in the solid-state imaging device 1J in the eleventh embodiment, a p-type substrate 81, an n-type substrate 82, an n-type stacked material portion 71, a p-type stacked material portion 72, and a transparent electrode 44 are stacked in this order.

The p-type substrate 81 and the n-type substrate 82 are equipped with an electronic readout circuit. An n-type electrode region 811, an n-type well region 812, and a p-type electrode region 813 are formed in the p-type substrate 81. An n-type contact region 821 is formed in the n-type substrate 82.

The n-type contact region 821 is electrically connected to the n-type stacked material portion 71 and serves as a cathode. Furthermore, the n-type contact region 821 is electrically connected to the n-type electrode region 811. The n-type electrode region 811 is connected to a logic circuit not illustrated.

Therefore, in a pixel P, a negative voltage higher than a breakdown voltage applied to the n-type stacked material portion 71 may be supplied from the logic circuit (not illustrated) to the n-type contact region 821 serving as the cathode. Furthermore, in the pixel P, bias adjustment on the p-type stacked material portion 72 via the transparent electrode 44 may be enabled.

In the solid-state imaging device 1J having the above-described configuration, the light is applied, the applied light is transmitted through the on-chip lens 50, and the transmitted light is photoelectrically converted by the n-type stacked material portion 71 and the p-type stacked material portion 72, so that an electron is generated and multiplied. Then, the multiplied electrons are read out from the n-type contact region 821 serving as the cathode and output as a pixel signal by a vertical signal line 153 illustrated in FIG. 1 via the n-type electrode region 811 of the p-type substrate 81.

### Action and Effect by Eleventh Embodiment

As described above, according to the eleventh embodiment, by forming the electronic readout circuit in the p-type substrate 81 and the n-type substrate 82, a copper (Cu)-copper (Cu) joining cost may be reduced.

### Variation of Eleventh Embodiment

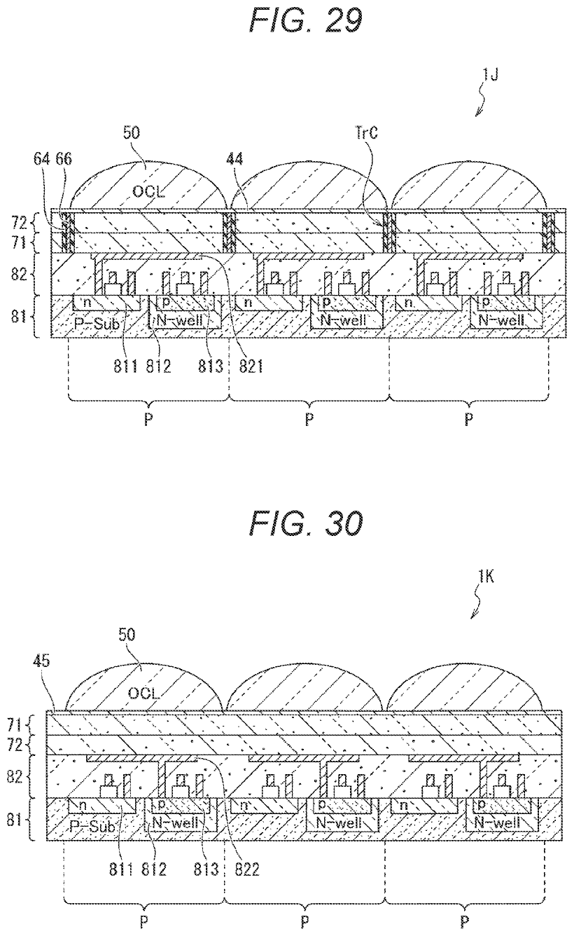

FIG. 29 is a cross-sectional view illustrating an example of a solid-state imaging device 1J in a variation of the eleventh embodiment of the present technology. In FIG. 29, the same portion as that in FIG. 28 described above is denoted by the same reference sign, and detailed description thereof is omitted.

As illustrated in FIG. 29, a back surface trench TrC is provided in an n-type stacked material portion 71 and a p-type stacked material portion 72 in the variation of the eleventh embodiment. The back surface trench TrC is obtained by sandwiching a metal film 66 from both sides by insulating films 64.

### Action and Effect by Variation of Eleventh Embodiment

As described above, according to the variation of the eleventh embodiment, action and effect similar to those of the eleventh embodiment described above may be obtained.

### Twelfth Embodiment

FIG. 30 is a cross-sectional view illustrating an example of a solid-state imaging device 1K in a twelfth embodiment of the present technology. In FIG. 30, the same portion as that in FIG. 28 described above is denoted by the same reference sign, and detailed description thereof is omitted.

As illustrated in FIG. 30, in the solid-state imaging device 1K in the twelfth embodiment, a p-type substrate 81, an n-type substrate 82, a p-type stacked material portion 72, an n-type stacked material portion 71, and a transparent electrode 45 serving as a cathode are stacked in this order.

The p-type substrate 81 and the n-type substrate 82 are equipped with a hole readout circuit. A p-type contact region 822 is formed in the n-type substrate 82.

The p-type contact region 822 is electrically connected to the p-type stacked material portion 72 and serves as an anode. Furthermore, the p-type contact region 822 is electrically connected to a p-type electrode region 813 formed in an n-type well region 812. The p-type electrode region 813 is connected to a logic circuit not illustrated.

Therefore, in a pixel P, a negative voltage higher than a breakdown voltage applied to the p-type stacked material portion 72 may be supplied from the logic circuit (not illustrated) to the p-type contact region 822 serving as the anode. Furthermore, in the pixel P, bias adjustment on the n-type stacked material portion 72 via the transparent electrode 45 may be enabled.

In the solid-state imaging device 1K having the above-described configuration, the light is applied, the applied light is transmitted through the on-chip lens 50, and the transmitted light is photoelectrically converted by the n-type stacked material portion 71 and the p-type stacked material portion 72, so that a hole is generated and multiplied. Then, the multiplied holes are read out from the p-type contact region 822 serving as the anode and output as a pixel signal by a vertical signal line 153 illustrated in FIG. 1 via the p-type electrode region 813 of the p-type substrate 81.

### Action and Effect by Twelfth Embodiment

As described above, according to the twelfth embodiment, by forming the hole readout circuit in the p-type substrate 81 and the n-type substrate 82, a copper (Cu)-copper (Cu) joining cost may be reduced.

### Variation of Twelfth Embodiment

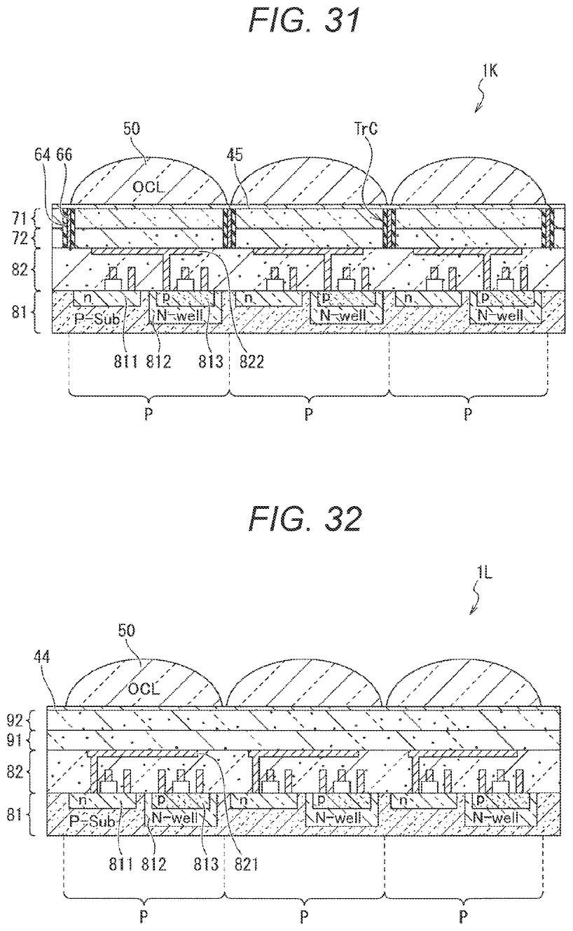

FIG. 31 is a cross-sectional view illustrating an example of a solid-state imaging device 1K in a variation of the twelfth embodiment of the present technology. In FIG. 31, the same portion as that in FIG. 30 described above is denoted by the same reference sign, and detailed description thereof is omitted.

As illustrated in FIG. 31, a back surface trench TrC is provided in an n-type stacked material portion 71 and a p-type stacked material portion 72 in the variation of the twelfth embodiment. The back surface trench TrC is obtained by sandwiching a metal film 66 from both sides by insulating films 64.

### Action and Effect by Variation of Twelfth Embodiment

As described above, according to the variation of the twelfth embodiment, action and effect similar to those of the twelfth embodiment described above may be obtained.

### Thirteenth Embodiment

FIG. 32 is a cross-sectional view illustrating an example of a solid-state imaging device 1L in a thirteenth embodiment of the present technology. In FIG. 32, the same portion as that in FIG. 28 described above is denoted by the same reference sign, and detailed description thereof is omitted.

As illustrated in FIG. 32, in the solid-state imaging device 1L in the thirteenth embodiment, a p-type substrate 81, an n-type substrate 82, an n-type stacked material portion 91, a p-type stacked material portion 92, and a transparent electrode 44 are stacked in this order.

In the n-type stacked material portion 91 and the p-type stacked material portion 92, a semiconductor material by an organic film that lattice-matches with a substrate 10 is used. For example, F6-OC6F5 and the like are used for silicon in the semiconductor material included in the n-type stacked material portion 91 and the p-type stacked material portion 92.

The p-type substrate 81 and the n-type substrate 82 are equipped with an electronic readout circuit. An n-type electrode region 811, an n-type well region 812, and a p-type electrode region 813 are formed in the p-type substrate 81. An n-type contact region 821 is formed in the n-type substrate 82.

The n-type contact region 821 is electrically connected to the n-type stacked material portion 91 and serves as a cathode. Furthermore, the n-type contact region 821 is electrically connected to the n-type electrode region 811. The n-type electrode region 811 is connected to a logic circuit not illustrated.

Therefore, in a pixel P, a negative voltage higher than a breakdown voltage applied to the n-type stacked material portion 91 may be supplied from the logic circuit (not illustrated) to the n-type contact region 821 serving as the cathode. Furthermore, in the pixel P, bias adjustment on the p-type stacked material portion 92 via the transparent electrode 44 may be enabled.

In the solid-state imaging device 1L having the above-described configuration, the light is applied, the applied light is transmitted through the on-chip lens 50, and the transmitted light is photoelectrically converted by the n-type stacked material portion 91 and the p-type stacked material portion 92, so that an electron is generated and multiplied. Then, the multiplied electrons are read out from the n-type contact region 821 serving as the cathode and output as a pixel signal by a vertical signal line 153 illustrated in FIG. 1 via the n-type electrode region 811 of the p-type substrate 81.

### Action and Effect by Thirteenth Embodiment

As described above, according to the thirteenth embodiment, action and effect similar to those of the eleventh embodiment described above may be obtained.

### Variation of Thirteenth Embodiment

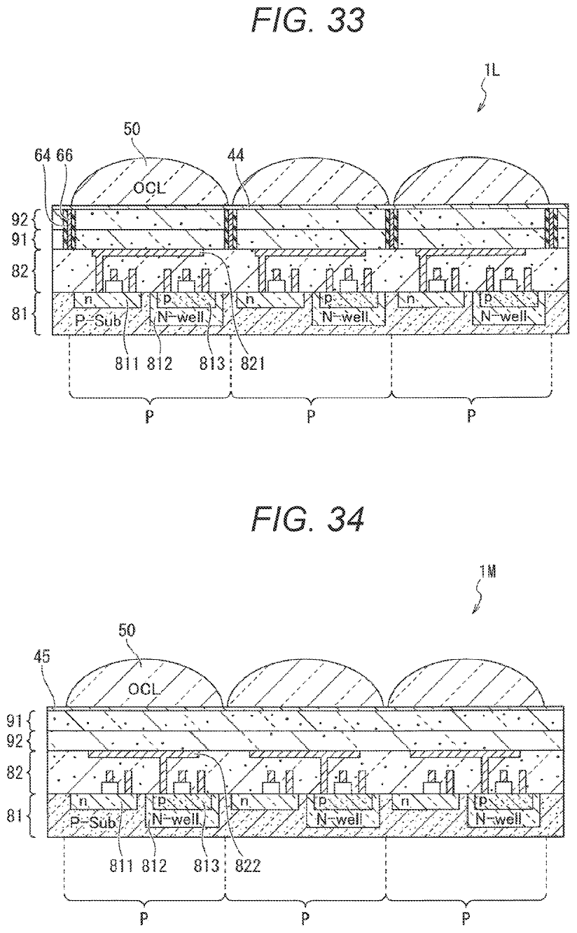

FIG. 33 is a cross-sectional view illustrating an example of a solid-state imaging device 1L in a variation of the thirteenth embodiment of the present technology. In FIG. 33, the same portion as that in FIG. 32 described above is denoted by the same reference sign, and detailed description thereof is omitted.

As illustrated in FIG. 33, a back surface trench TrC is provided in an n-type stacked material portion 91 and a p-type stacked material portion 92 in the variation of the thirteenth embodiment. The back surface trench TrC is obtained by sandwiching a metal film 66 from both sides by insulating films 64.

### Action and Effect by Variation of Thirteenth Embodiment

As described above, according to the variation of the thirteenth embodiment, action and effect similar to those of the thirteenth embodiment described above may be obtained.

### Fourteenth Embodiment

FIG. 34 is a cross-sectional view illustrating an example of a solid-state imaging device 1M in a fourteenth embodiment of the present technology. In FIG. 34, the same portion as that in FIG. 32 described above is denoted by the same reference sign, and detailed description thereof is omitted.

As illustrated in FIG. 34, in the solid-state imaging device 1M in the fourteenth embodiment, a p-type substrate 81, an n-type substrate 82, a p-type stacked material portion 92, an n-type stacked material portion 91, and a transparent electrode 45 serving as a cathode are stacked in this order.

The p-type substrate 81 and the n-type substrate 82 are equipped with a hole readout circuit. A p-type contact region 822 is formed in the n-type substrate 82.

The p-type contact region 822 is electrically connected to the p-type stacked material portion 92 and serves as an anode. Furthermore, the p-type contact region 822 is electrically connected to a p-type electrode region 813 formed in an n-type well region 812. The p-type electrode region 813 is connected to a logic circuit not illustrated.

Therefore, in a pixel P, a negative voltage higher than a breakdown voltage applied to the p-type stacked material portion 92 may be supplied from the logic circuit (not illustrated) to the p-type contact region 822 serving as the anode. Furthermore, in the pixel P, bias adjustment on the n-type stacked material portion 92 via the transparent electrode 45 may be enabled.

In the solid-state imaging device 1M having the above-described configuration, the light is applied, the applied light is transmitted through the on-chip lens 50, and the transmitted light is photoelectrically converted by the n-type stacked material portion 91 and the p-type stacked material portion 92, so that a hole is generated and multiplied. Then, the multiplied holes are read out from the p-type contact region 822 serving as the anode and output as a pixel signal by a vertical signal line 153 illustrated in FIG. 1 via the p-type electrode region 813 of the p-type substrate 81.

### Action and Effect by Fourteenth Embodiment

As described above, according to the fourteenth embodiment, action and effect similar to those of the twelfth embodiment described above may be obtained.

### Variation of Fourteenth Embodiment

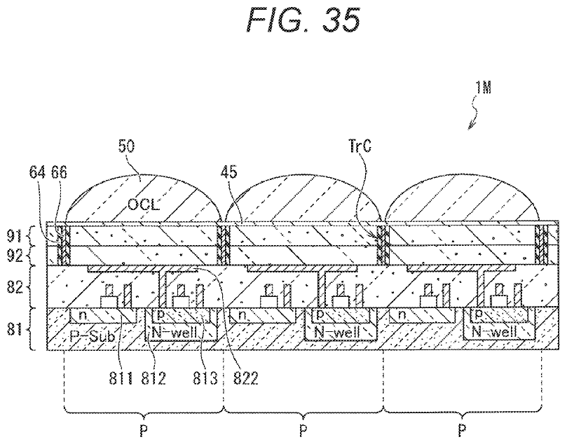

FIG. 35 is a cross-sectional view illustrating an example of a solid-state imaging device 1M in a variation of the fourteenth embodiment of the present technology. In FIG. 35, the same portion as that in FIG. 34 described above is denoted by the same reference sign, and detailed description thereof is omitted.

As illustrated in FIG. 35, a back surface trench is provided in an n-type stacked material portion 91 and a p-type stacked material portion 92 in the variation of the fourteenth embodiment. The back surface trench is obtained by sandwiching a metal film 66 from both sides by insulating films 64.

### Action and Effect by Variation of Fourteenth Embodiment

As described above, according to the variation of the fourteenth embodiment, action and effect similar to those of the fourteenth embodiment described above may be obtained.

### Other Embodiment

As described above, the present technology is described according to the first to fourteenth embodiments and variations thereof, but it should not be understood that the description and drawings forming a part of this disclosure limit the present technology. It will be apparent to those skilled in the art that various alternative embodiments, examples, and operation techniques might be included in the present technology by understanding the spirit of the technical content disclosed in the first to fourteenth embodiments described above. Furthermore, the configurations disclosed in the first to fourteenth embodiments and the variations thereof may be appropriately combined within a range in which no contradiction occurs. For example, the configurations disclosed by a plurality of different embodiments may be combined, or the configurations disclosed by a plurality of different variations of the same embodiment may be combined.

<Configuration Example of Light Receiving Element>

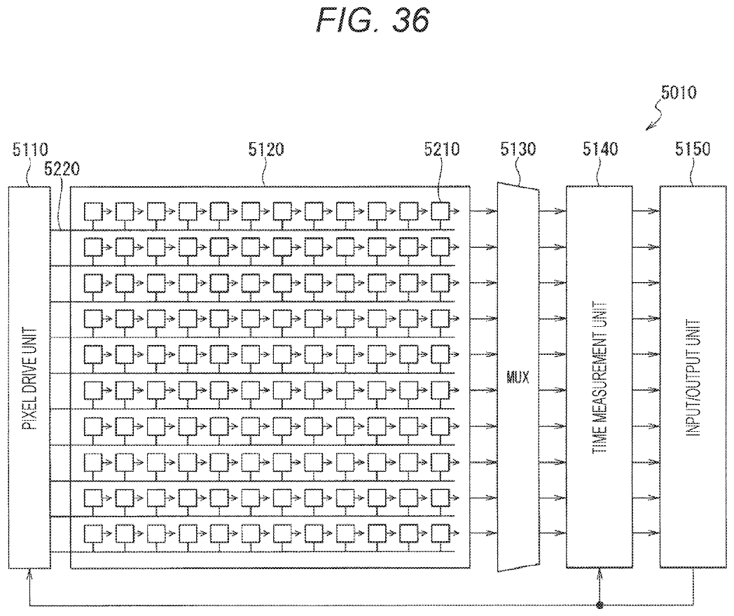

The pixel P according to the first to fourteenth embodiments described above may be applied to, for example, a pixel of a light receiving element illustrated in FIG. 36.

FIG. 36 is a block diagram of the light receiving element including the pixel P described above.

A light receiving element 5010 in FIG. 36 is provided with a pixel drive unit 5110, a pixel array 5120, a multiplexer (MUX) 5130, a time measurement unit 5140, and an input/output unit 5150.

The pixel array 5120 has a configuration in which pixels 5210 that detect incidence of a photon and output a detection signal PFout indicating a detection result as a pixel signal are two-dimensionally arranged in a matrix in a row direction and a column direction. Here, the row direction refers to an arrangement direction of the pixels 5210 of a pixel row, that is, a horizontal direction, and the column direction refers to an arrangement direction of the pixels 5210 of a pixel column, that is, a vertical direction. In FIG. 36, the pixel array 5120 is illustrated in a pixel arrangement configuration of 10 rows and 12 columns due to paper surface restriction, but the number of rows and the number of columns of the pixel array 5120 are not limited thereto and may be any number.

The pixel drive line 5220 is wired in the horizontal direction for each pixel row with respect to a matrix-shaped pixel arrangement of the pixel array 5120. The pixel drive line 5220 transmits a drive signal for driving the pixel 5210. The pixel drive unit 5110 drives each pixel 5210 by supplying a predetermined drive signal to each pixel 5210 via the pixel drive line 5220. Specifically, the pixel drive unit 5110 performs control so that some pixels 5210 out of the plurality of pixels 5210 two-dimensionally arranged in a matrix shape are set as active pixels and the remaining pixels 5210 are set as inactive pixels at a predetermined timing corresponding to a light emission timing signal externally supplied via the input/output unit 5150. The active pixel is a pixel that detects incidence of a photon, and the inactive pixel is a pixel that does not detect incidence of a photon. As the configuration of the pixel 5210, any one of the first to fourteenth embodiments of the pixel P described above may be adopted.

Note that, in FIG. 36, the pixel drive line 5220 is illustrated as one wiring, but this may include a plurality of pieces of wiring. One end of the pixel drive line 5220 is connected to an output end corresponding to each pixel row of the pixel drive unit 5110.

The MUX 5130 selects an output from the active pixel according to switching between the active pixel and the inactive pixel in the pixel array 5120. Then, the MUX 5130 outputs the pixel signal input from the selected active pixel to the time measurement unit 5140.

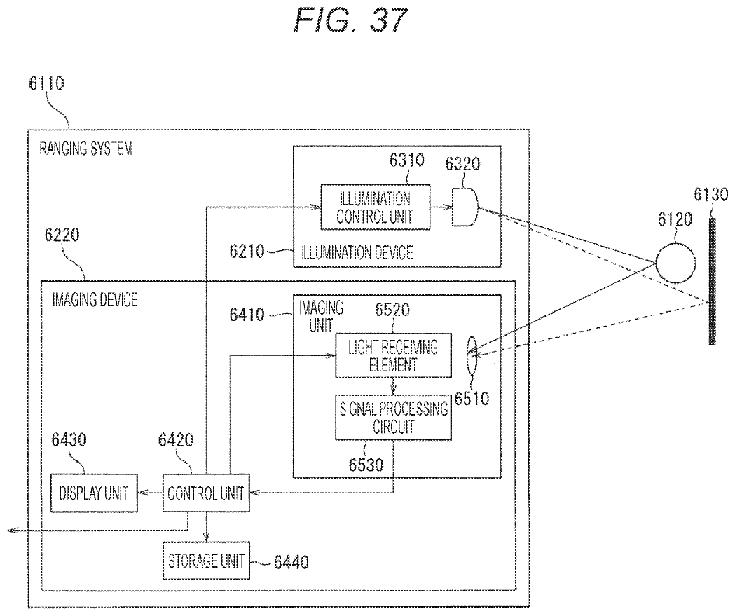

On the basis of the pixel signal of the active pixel supplied from the MUX 5130 and the light emission timing signal indicating a light emission timing of a light emission source (a light source 6320 in FIG. 37), the time measurement unit 5140 generates a count value corresponding to time from when the light emission source emits light to when the active pixel receives the light. The light emission timing signal is supplied from outside (a controller 6420 of an imaging device 6220 in FIG. 37) via the input/output unit 5150.

The input/output unit 5150 outputs the count value of the active pixel supplied from the time measurement unit 5140 to outside (a signal processing circuit 6530 in FIG. 37) as the pixel signal. Furthermore, the input/output unit 5150 supplies the light emission timing signal supplied from outside to the pixel drive unit 5110 and the time measurement unit 5140.

<Configuration Example of Ranging System>

FIG. 37 is a block diagram illustrating a configuration example of an embodiment of a ranging system in which the light receiving element 5010 in FIG. 36 is incorporated.

The ranging system 6110 is, for example, a system that images a distance image using a ToF method. Here, the distance image is an image including a distance pixel signal based on a detected distance, the distance in a depth direction from the ranging system 6110 to the subject detected for each pixel.

The ranging system 6110 is provided with an illumination device 6210 and an imaging device 6220.

The illumination device 6210 is provided with an illumination controller 6310 and a light source 6320.

The illumination controller 6310 controls a pattern in which the light source 6320 applies light under the control of the controller 6420 of the imaging device 6220. Specifically, the illumination controller 6310 controls the pattern in which the light source 6320 applies light according to an irradiation code included in an irradiation signal supplied from the controller 6420. For example, the irradiation code has two values of 1 (high) and 0 (low), and the illumination controller 6310 turns on the light source 6320 when the value of the irradiation code is 1 and turns off the light source 6320 when the value of the irradiation code is 0.

The light source 6320 emits light in a predetermined wavelength region under the control of the illumination controller 6310. The light source 6320 includes, for example, an infrared laser diode. Note that a type of the light source 6320 and a wavelength range of irradiation light may be optionally set according to an application of the ranging system 6110 and the like.

The imaging device 6220 is a device that receives reflected light, the light applied from the illumination device 6210 (irradiation light) reflected by a subject 6120, a subject 6130 and the like. The imaging device 6220 is provided with an imaging unit 6410, a controller 6420, a display unit 6430, and a storage unit 6440.

The imaging unit 6410 is provided with a lens 6510, a light receiving element 6520, and a signal processing circuit 6530.

The lens 6510 forms an image of incident light on a light receiving surface of the light receiving element 6520. Note that the lens 6510 may be optionally configured, and for example, the lens 6510 may be configured by a plurality of lens groups.

The light receiving element 6520 includes, for example, a sensor using an SPAD for each pixel. Under the control of the controller 6420, the light receiving element 6520 receives reflected light from the subject 6120, the subject 6130 and the like, and supplies a pixel signal obtained as a result to the signal processing circuit 6530. This pixel signal indicates a digital count value obtained by counting time from when the illumination device 6210 applies the irradiation light to when the light receiving element 6520 receives the light. The light emission timing signal indicating a timing at which the light source 6320 emits light is also supplied from the controller 6420 to the light receiving element 6520. As a configuration of the light receiving element 6520, the light receiving element 5010 in FIG. 36 provided with the pixel P described above is adopted.

The signal processing circuit 6530 processes the pixel signal supplied from the light receiving element 6520 under the control of the controller 6420. For example, the signal processing circuit 6530 detects the distance to the subject for each pixel on the basis of the pixel signal supplied from the light receiving element 6520, and generates a distance image indicating the distance to the subject for each pixel. Specifically, the signal processing circuit 6530 obtains time (count value) from when the light source 6320 emits light to when each pixel of the light receiving element 6520 receives the light a plurality of times (for example, thousands to tens of thousands of times) for each pixel. The signal processing circuit 6530 creates a histogram corresponding to the obtained time. Then, by detecting a peak of the histogram, the signal processing circuit 6530 determines the time until the light applied from the light source 6320 is reflected by the subject 6120 or the subject 6130 to return. Moreover, the signal processing circuit 6530 performs an arithmetic operation to obtain the distance to the object on the basis of the determined time and light speed. The signal processing circuit 6530 supplies the generated distance image to the controller 6420.

The controller 6420 includes, for example, a control circuit such as a field programmable gate array (FPGA) or a digital signal processor (DSP), a processor and the like. The controller 6420 controls the illumination controller 6310 and the light receiving element 6520. Specifically, the controller 6420 supplies the irradiation signal to the illumination controller 6310 and supplies the light emission timing signal to the light receiving element 6520. The light source 6320 emits the irradiation light according to the irradiation signal. The light emission timing signal may be the irradiation signal supplied to the illumination controller 6310. Furthermore, the controller 6420 supplies the distance image obtained from the imaging unit 6410 to the display unit 6430 and allows the display unit 6430 to display the same. Moreover, the controller 6420 stores the distance image obtained from the imaging unit 6410 in the storage unit 6440.

Furthermore, the controller 6420 outputs the distance image obtained from the imaging unit 6410 to outside.

The display unit 6430 includes, for example, a panel display device such as a liquid crystal display device or an organic electro luminescence (EL) display device.

The storage unit 6440 may include any storage device, storage medium and the like, and stores the distance image and the like.

By adopting the structure of the pixel P described above in the light receiving element 5010 and the ranging system 6110 described above, it is possible to generate and output the distance image achieving high photon detection efficiency (PDE) while preventing edge break.

<Application Example to Electronic Device 1>

The above-described ranging system 6110 may be mounted on, for example, an electronic device such as a smartphone, a tablet terminal, a mobile phone, a personal computer, a game machine, a television receiver, a wearable terminal, a digital still camera, and a digital video camera.

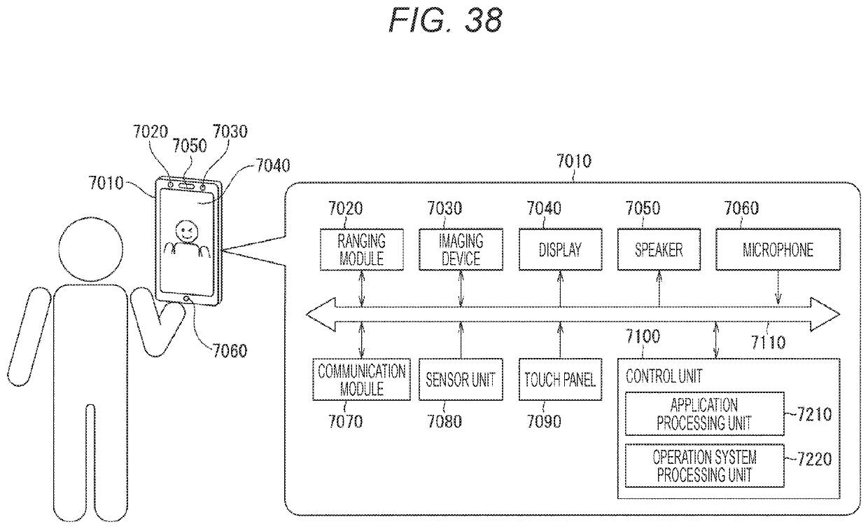

FIG. 38 is a block diagram illustrating a configuration example of a smartphone as an electronic device equipped with a ranging system 6110.

As illustrated in FIG. 38, a smartphone 7010 is formed by connecting a ranging module 7020, an imaging device 7030, a display 7040, a speaker 7050, a microphone 7060, a communication module 7070, a sensor unit 7080, a touch panel 7090, and a control unit 7100 via a bus 7110. Furthermore, the control unit 7100 has functions as an application processing unit 7210 and an operation system processing unit 7220 by a CPU executing a program.

The ranging system 6110 in FIG. 37 is applied to the ranging module 7020. For example, the ranging module 7020 is arranged on a front surface of the smartphone 7010, and may perform ranging on a user of the smartphone 7010 to output a depth value of a surface shape of the face, hand, finger and the like of the user as a ranging result.

The imaging device 7030 is arranged on the front surface of the smartphone 7010, and performs imaging of the user of the smartphone 7010 as a subject to obtain an image in which the user is imaged. Note that, although not illustrated, the imaging device 7030 may also be arranged on a rear surface of the smartphone 7010.

The display 7040 displays an operation screen for performing processing by the application processing unit 7210 and the operation system processing unit 7220, the image imaged by the imaging device 7030 and the like. The speaker 7050 and the microphone 7060 output a voice of the other party and collect a voice of the user, for example, when talking on the smartphone 7010.

The communication module 7070 performs communication via a communication network. The sensor unit 7080 senses speed, acceleration, proximity and the like, and the touch panel 7090 obtains a touch operation by the user on an operation screen displayed on the display 7040.

The application processing unit 7210 performs processing for providing various services by the smartphone 7010. For example, the application processing unit 7210 may perform processing of creating a face by computer graphics virtually reproducing an expression of the user on the basis of a depth map supplied from the ranging module 7020 and displaying the same on the display 7040. Furthermore, the application processing unit 7210 may perform processing of creating three-dimensional shape data of any solid object, for example, on the basis of the depth map supplied from the ranging module 7020.

The operation system processing unit 7220 performs processing for implementing basic functions and operations of the smartphone 7010. For example, the operation system processing unit 7220 may perform processing of authenticating the face of the user and unlocking the smartphone 7010 on the basis of the depth map supplied from the ranging module 7020. Furthermore, on the basis of the depth map supplied from the ranging module 7020, the operation system processing unit 7220 may perform, for example, processing of recognizing a gesture of the user and processing of inputting various operations according to the gesture.

In the smartphone 7010 configured in this manner, for example, the depth map may be generated with high accuracy and at high speed by applying the above-described ranging system 6110. Therefore, the smartphone 7010 may more accurately detect ranging information.

<Application Example to Electronic Device 2>

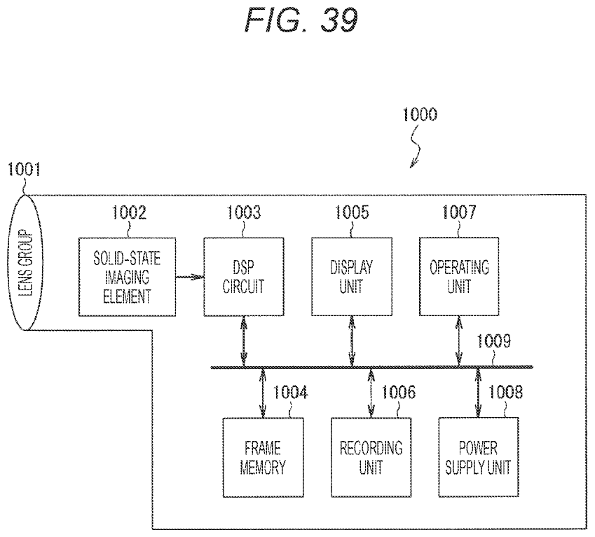

FIG. 39 is a block diagram illustrating a configuration example of an embodiment of an imaging device as an electronic device to which the present technology is applied.

An imaging device 1000 in FIG. 39 is a video camera, a digital still camera and the like. The imaging device 1000 includes a lens group 1001, a solid-state imaging element 1002, a DSP circuit 1003, a frame memory 1004, a display unit 1005, a recording unit 1006, an operating unit 1007, and a power supply unit 1008. The DSP circuit 1003, the frame memory 1004, the display unit 1005, the recording unit 1006, the operating unit 1007, and the power supply unit 1008 are connected to one another via a bus line 1009.

The lens group 1001 captures incident light (image light) from a subject and forms an image on an imaging surface of the solid-state imaging element 1002. The solid-state imaging element 1002 is of the first to fourteenth embodiments of the solid-state imaging device described above. The solid-state imaging element 1002 converts an amount of the incident light the image of which is formed on the imaging surface by the lens group 1001 to an electrical signal for each pixel to supply to the DSP circuit 1003 as a pixel signal.

The DSP circuit 1003 performs predetermined image processing on the pixel signal supplied from the solid-state imaging element 1002 and supplies the image signal after the image processing to the frame memory 1004 for each frame to temporarily store.

The display unit 1005 includes a panel display device such as a liquid crystal panel and an organic electro luminescence (EL) panel, for example, and displays an image on the basis of the pixel signal for each frame temporarily stored in the frame memory 1004.

The recording unit 1006 includes a digital versatile disk (DVD), a flash memory and the like, and reads the pixel signal for each frame temporarily stored in the frame memory 1004 to record.

The operating unit 1007 issues an operation command regarding various functions of the imaging device 1000 under operation by a user. The power supply unit 1008 appropriately supplies power to the DSP circuit 1003, the frame memory 1004, the display unit 1005, the recording unit 1006, and the operating unit 1007.

It is sufficient that the electronic device to which the present technology is applied is a device in which the solid-state imaging device is used as an image capturing unit (photoelectric converting unit); there is a portable terminal device having an imaging function, a copying machine using a solid-state imaging device as an image reading unit and the like in addition to the imaging device 1000.

<Usage Example of Solid-State Imaging Device>

The above-described solid-state imaging device may be used in various cases in which light such as visible light, infrared light, ultraviolet light, and X-ray is sensed as described below, for example.
A device that images an image to be used for viewing such as a digital camera and a portable device with a camera function
A device for traffic purpose such as an in-vehicle sensor that images the front, rear, surroundings, interior and the like of an automobile, a surveillance camera for monitoring traveling vehicles and roads, and a ranging sensor that measures a distance between vehicles for safe driving such as automatic stop, recognition of a driver's condition and the like
A device for home appliance such as a television, a refrigerator, and an air conditioner that images a user's gesture and performs device operation according to the gesture
A device for medical and health care use such as an endoscope and a device that performs angiography by receiving infrared light
A device for security use such as a security monitoring camera and an individual authentication camera
A device for beauty care such as a skin measuring device that images skin and a microscope that images scalp
A device for sporting use such as an action camera and a wearable camera for sporting use and the like
A device for agricultural use such as a camera for monitoring land and crop states

Note that, the effects described in this specification are illustrative only and are not limitative; there may also be another effect.

Note that, the present disclosure may also have the following configuration.

(1)

A semiconductor device including:

a plurality of pixels in each of which an avalanche photodiode element that photoelectrically converts incident light is formed,

each of the plurality of pixels provided with:

a substrate including a first semiconductor material; and

a stacked portion stacked on a surface on a light incident side of the substrate and including a second semiconductor material different from the first semiconductor material.

(2)

The semiconductor device according to (1) described above, in which the substrate is provided with

a multiplication unit including a first electrode region of a first conductivity type provided on a surface on a side opposite to the surface on the light incident side of the substrate, and a second electrode region of a second conductivity type provided so as to form a pn junction with the first electrode region, in which an avalanche multiplication region is formed on an interface of the pn junction.

(3)

The semiconductor device according to (2) described above, in which

the stacked portion is a light absorption layer, and

the multiplication unit is a Geiger multiplication unit that performs avalanche multiplication on a carrier photoelectrically converted by the light absorption layer.

(4)

The semiconductor device according to (2) described above, in which

the stacked portion is a linear multiplication unit that performs avalanche multiplication on a photoelectrically converted carrier, and

the multiplication unit is a Geiger multiplication unit that performs avalanche multiplication on carriers multiplied by the linear multiplication unit.

(5)

The semiconductor device according to (1) described above, in which

the stacked portion is a Geiger multiplication unit that performs avalanche multiplication on a photoelectrically converted carrier, and

a readout circuit that reads carriers multiplied by the Geiger multiplication unit is further formed in the substrate.

(6)

The semiconductor device according to (3) or (4) described above, in which the stacked portion uses a substance crystal growth of which is possible as the second semiconductor material.

(7)

The semiconductor device according to (6) described above, in which the stacked portion has a stacked structure by the crystal growth including a transitional layer.

(8)

The semiconductor device according to (6) described above, in which the stacked portion has a stacked structure by lattice-matched crystal growth.

(9)

The semiconductor device according to (8) described above, in which the stacked structure by the lattice-matched crystal growth is a quantum well type or quantum dot type stacked structure.

(10)

The semiconductor device according to any one of (3) to (5) described above, in which the stacked portion uses a nano crystal as the second semiconductor material.

(11)

The semiconductor device according to any one of (3) to (5) described above, in which the stacked portion uses an organic film as the second semiconductor material.

(12)

The semiconductor device according to any one of (1) to (11) described above, further including: a pixel isolation unit that insulates and isolates a plurality of adjacent pixels from each other.

(13)

The semiconductor device according to (12) described above, in which the pixel isolation unit performs pixel isolation by a full trench formed from the substrate to the stacked portion.

(14)

The semiconductor device according to (12) described above, in which the pixel isolation unit performs pixel isolation by a rear surface trench formed in the stacked portion.

(15)

The semiconductor device according to (12) described above, in which the pixel isolation unit performs pixel isolation by a front surface trench formed in the substrate.

(16)

The semiconductor device according to any one of (11) to (15) described above, further including: an on-chip lens provided on a light incident side of each of the plurality of pixels.

(17)

The semiconductor device according to any one of (11) to (16) described above, in which the plurality of pixels is provided with an antireflection unit that prevents reflection of the incident light.

(18)

An electronic device including:

a semiconductor device provided with:

a plurality of pixels in each of which an avalanche photodiode element that photoelectrically converts incident light is formed,

each of the plurality of pixels provided with:

a substrate including a first semiconductor material; and

a stacked portion stacked on a surface on a light incident side of the substrate and including a second semiconductor material different from the first semiconductor material.

### REFERENCE SIGNS LIST

1A, 1B, 1C, 1D, 1E, 1F, 1G, 1H, 1I, 1J, 1K, 1L, 1M Solid-state imaging device
2, 5 SPAD element
3 Light absorption unit
4 Geiger multiplication unit
6 Linear multiplication unit
10, 81, 82 Substrate
11 First electrode region
12 Second electrode region
13 Avalanche multiplication region
14, 61, 67, 68, 812 Well region
20 Transitional layer
30, 31, 32, 33, 34, 70, 71, 72, 91, 92 Stacked material portion
40 Wiring layer
41 Wiring
42 Cathode
43 Anode
44, 45 Transparent electrode
50 On-chip lens
60, 60A, 60B, 60C, 60D, 60E, 60F Pixel isolation unit
62 Interlayer film
63, 65, 66 Metal film
64 Insulating film
102 Constant current source
103 Transistor
104 Inverter
811, 813 Electrode region
821, 822 Contact region
1000, 6220, 7030 Imaging device
1001 Lens group
1002 Solid-state imaging element
1003 DSP circuit
1004 Frame memory
1005 Display unit
1006 Recording unit
1007 Operating unit
1008 Power supply unit
1009 Bus line
5010 Light receiving element
5110 Pixel drive unit
5120 Pixel array
5140 Time measurement unit
5150 Input/output unit
5210, P Pixel
5220 Pixel drive line
6110 Ranging system
6120 Subject
6130 Subject
6210 Illumination device
6310 Illumination controller
6320 Light source
6410 Imaging unit
6420 Controller
6430 Display unit
6440 Storage unit
6510 Lens
6520 Light receiving element
6530 Signal processing circuit
7010 Smartphone
7020 Ranging module
7040 Display
7050 Speaker
7060 Microphone
7070 Communication module
7080 Sensor unit
7090 Touch panel
7100 Control unit
7110 Bus
7210 Application processing unit
7220 Operation system processing unit
TrA Full trench
TrB Front surface trench
TrC Back surface trench

What is claimed is:

1. A semiconductor device comprising:
a plurality of pixels in each of which an avalanche photodiode element that photoelectrically converts incident light is formed,
each of the plurality of pixels provided with:
a substrate including a first semiconductor material; and
a stacked portion stacked on a surface on a light incident side of the substrate and including a second semiconductor material different from the first semiconductor material.

2. The semiconductor device according to claim 1, wherein the substrate is provided with
a multiplication unit including a first electrode region of a first conductivity type provided on a surface on a side opposite to the surface on the light incident side of the substrate, and a second electrode region of a second conductivity type provided so as to form a pn junction with the first electrode region, in which an avalanche multiplication region is formed on an interface of the pn junction.

3. The semiconductor device according to claim 2, wherein
the stacked portion is a light absorption layer, and
the multiplication unit is a Geiger multiplication unit that performs avalanche multiplication on a carrier photoelectrically converted by the light absorption layer.

4. The semiconductor device according to claim 2, wherein
the stacked portion is a linear multiplication unit that performs avalanche multiplication on a photoelectrically converted carrier, and
the multiplication unit is a Geiger multiplication unit that performs avalanche multiplication on carriers multiplied by the linear multiplication unit.

5. The semiconductor device according to claim 1, wherein
the stacked portion is a Geiger multiplication unit that performs avalanche multiplication on a photoelectrically converted carrier, and
a readout circuit that reads carriers multiplied by the Geiger multiplication unit is further formed in the substrate.

6. The semiconductor device according to claim 3, wherein the stacked portion uses a substance crystal growth of which is possible as the second semiconductor material.

7. The semiconductor device according to claim 6, wherein the stacked portion has a stacked structure by the crystal growth including a transitional layer.

8. The semiconductor device according to claim 6, wherein the stacked portion has a stacked structure by lattice-matched crystal growth.

9. The semiconductor device according to claim 8, wherein the stacked structure by the lattice-matched crystal growth is a quantum well type or quantum dot type stacked structure.

10. The semiconductor device according to claim 3, wherein the stacked portion uses a nano crystal as the second semiconductor material.

11. The semiconductor device according to claim 3, wherein the stacked portion uses an organic film as the second semiconductor material.

12. The semiconductor device according to claim 1, further comprising: a pixel isolation unit that insulates and isolates a plurality of adjacent pixels from each other.

13. The semiconductor device according to claim 12, wherein the pixel isolation unit performs pixel isolation by a full trench formed from the substrate to the stacked portion.

14. The semiconductor device according to claim 12, wherein the pixel isolation unit performs pixel isolation by a rear surface trench formed in the stacked portion.

15. The semiconductor device according to claim 12, wherein the pixel isolation unit performs pixel isolation by a front surface trench formed in the substrate.

16. The semiconductor device according to claim 1, further comprising: an on-chip lens provided on a light incident side of each of the plurality of pixels.

17. The semiconductor device according to claim 1, wherein the plurality of pixels is provided with an antireflection unit that prevents reflection of the incident light.

18. An electronic device comprising:
a semiconductor device provided with:
a plurality of pixels in each of which an avalanche photodiode element that photoelectrically converts incident light is formed,
each of the plurality of pixels provided with:
a substrate including a first semiconductor material; and
a stacked portion stacked on a surface on a light incident side of the substrate and including a second semiconductor material different from the first semiconductor material.
